(19) United States
(12) Patent Application Publication
(10) Pub. No.: US 2017/0025384 A1
(43) Pub. Date: Jan. 26, 2017

(54) SEMICONDUCTOR CHIP AND SEMICONDUCTOR PACKAGE HAVING THE SAME

(71) Applicant: SAMSUNG ELECTRONICS CO., LTD., Suwon-Si (KR)

(72) Inventors: MYEONG-SOON PARK, Goyang-Si (KR); HYUN-SOO CHUNG, Hwaseong-Si (KR); CHAN-HO LEE, Gwangmyeong-Si (KR)

(21) Appl. No.: 15/134,999

(22) Filed: Apr. 21, 2016

(30) Foreign Application Priority Data
Jul. 22, 2015 (KR) 10-2015-0103883

(51) Int. Cl. H01L 25/065

(52) U.S. Cl. CPC H01L 25/0657; H01L 2225/06513; H01L 2225/06544; H01L 2225/06593

(57) ABSTRACT

Provided are a semiconductor chip and a semiconductor package capable of obtaining stability and reliability through a connection structure using a through-silicon-via (TSV). The semiconductor chip includes a semiconductor substrate and a through-silicon-via (TSV) structure penetrating through the semiconductor substrate. A connection pad includes a foundation base disposed on a lower surface of the semiconductor substrate and connected to the TSV structure. A protruding portion protrudes from the foundation base and extend to an inside of a first groove formed in a lower surface of the semiconductor substrate.

### CROSS-REFERENCE TO RELATED APPLICATION

This application claims priority under 35 U.S.C. §119 to Korean Patent Application No. 10-2015-0103883, filed on Jul. 22, 2015, in the Korean Intellectual Property Office, the disclosure of which is incorporated by reference herein in its entirety.

### TECHNICAL FIELD

Exemplary embodiments of the present inventive concept relate to a semiconductor chip, and more particularly, to a semiconductor package having the same.

### DISCUSSION OF RELATED ART

As a three-dimensional (3D) package, including a plurality of semiconductor chips in one semiconductor package, is developed, technology for increasing reliability in a connection structure using a through-silicon-via (TSV) may be developed. An electrical connection formed vertically through a substrate or a die may also be developed.

### SUMMARY

Exemplary embodiments of the present inventive concept may provide a semiconductor chip having increased stability and reliability through a connection structure using a through-silicon-via (TSV) structure.

Exemplary embodiments of the present inventive concept may provide a semiconductor package having increased stability and reliability through a connection structure using a TSV structure.

According to an exemplary embodiment of the present inventive concept, a semiconductor chip includes a semiconductor substrate and a through-silicon-via (TSV) structure penetrating through the semiconductor substrate. A connection pad includes a foundation base disposed on a lower surface of the semiconductor substrate and connected to the TSV structure. A protruding portion protrudes from the foundation base and extend to an inside of a first groove formed in a lower surface of the semiconductor substrate.

The semiconductor chip may include a chip alignment mark including of a second groove formed in the lower surface of the semiconductor substrate. A depth of the first groove may be substantially the same as that of the second groove.

The semiconductor chip may include a lower insulating layer covering a part of the lower surface of the semiconductor substrate and inner surfaces of the first and second grooves. The lower insulating layer may define first and second recesses in the first and second grooves. The protruding portion of the connection pad may fill the first recess.

The semiconductor substrate may include a TSV region in which the TSV structure is arranged and an element region in which a plurality of individual devices is arranged. The chip alignment mark may be arranged in the element region.

The semiconductor chip may include a via insulating layer disposed between the TSV structure and the semiconductor substrate. The via insulating layer may surround a sidewall of the TSV structure. A part of an inner surface of the first groove may be a part of the sidewall of the TSV structure.

The semiconductor chip may include a via insulating layer disposed between the TSV structure and the semiconductor substrate. The via insulating layer may surround a sidewall of the TSV structure. The first groove may be spaced apart from the via insulating layer. A part of the semiconductor substrate may be arranged between the protruding portion of the connection pad and the via insulating layer.

The protruding portion may surround a lower side surface of the TSV structure.

A plurality of the protruding portions may be spaced apart from each other along a lower side surface of the TSV structure.

The semiconductor chip may include an interlayer insulating layer covering an upper surface of the semiconductor substrate. The TSV structure may penetrate through the semiconductor substrate and the interlayer insulating layer.

The semiconductor chip may include an interlayer insulating layer covering an upper surface of the semiconductor substrate. The TSV structure need not penetrate through the interlayer insulating layer while penetrating through the semiconductor substrate.

The semiconductor chip may include an interlayer insulating layer covering an upper surface of the semiconductor substrate and an inter-metal insulating layer covering the interlayer insulating layer. The TSV structure may penetrate through the semiconductor substrate, the interlayer insulating layer, and the inter-metal insulating layer.

According to another exemplary embodiment of the present inventive concept, a semiconductor package includes a plurality of semiconductor chips including a TSV structure penetrating a semiconductor substrate. The plurality of semiconductor chips is stacked and electrically connected to each other through the TSV structure. Each of the plurality of semiconductor chips includes a connection pad including a foundation base disposed on a lower surface of the semiconductor substrate and connected to the TSV structure, and a protruding portion which protrudes from the foundation base and extends to an inside of a first groove formed in a lower surface of the semiconductor substrate. A chip alignment mark is formed in the lower surface of the semiconductor substrate. The chip alignment mark includes a second groove having substantially a same depth as a depth of the first groove. The semiconductor chips each overlap the chip alignment mark corresponding another of the semiconductor chips.

Each semiconductor substrate of the plurality of semiconductor chips may include a TSV region in which the TSV structure is arranged and an element region in which a plurality of individual devices is arranged. The chip alignment mark may be formed in the element region.

Each of the plurality of semiconductor chips may include a lower insulating layer covering a part of the lower surface of the semiconductor substrate and inner surfaces of the first and second grooves. The lower insulating layer may define first and second recesses in the first and second grooves. The protruding portion of the connection pad may fill the first recess.

The semiconductor package may include a package substrate. Each of the plurality of semiconductor chips may include a connection terminal which is electrically connected to the TSV structure and attached on an upper surface of the semiconductor substrate. The upper surface of the semiconductor substrate may be stacked on the package substrate to face the package substrate.

### BRIEF DESCRIPTION OF THE DRAWINGS

The above and other features of the inventive concept will become more apparent by describing in detail exemplary embodiments thereof, with reference to the accompanying drawing, in which:

FIG. 1 is a cross-sectional view of a semiconductor chip according to an exemplary embodiment of the present inventive concept;

FIG. 2 is a cross-sectional view of a semiconductor chip according to another exemplary embodiment of the present inventive concept;

FIG. 3 is a cross-sectional view of a semiconductor chip according to another exemplary embodiment of the present inventive concept;

FIG. 4 is a cross-sectional view of a semiconductor chip according to another exemplary embodiment of the present inventive concept;

FIG. 5 is a cross-sectional view of a semiconductor chip according to another exemplary embodiment of the present inventive concept;

FIG. 6 is a cross-sectional view illustrating a schematic configuration of a semiconductor package according to an exemplary embodiment of the present inventive concept;

FIG. 7 is a plan view illustrating a rear surface of a semiconductor chip according to an exemplary embodiment of the present inventive concept;

FIGS. 8A through 8H are plan views illustrating a configuration of a connection pad included in a semiconductor chip and a semiconductor package, according to an exemplary embodiment of the present inventive concept;

FIGS. 9A through 9R are cross-sectional views of a method of manufacturing a semiconductor chip according to an exemplary embodiment of the present inventive concept;

FIG. 10 is a cross-sectional view of a method of manufacturing a semiconductor chip according to an exemplary embodiment of the present inventive concept;

FIG. 11 is a cross-sectional view showing elements of a semiconductor package according to an exemplary embodiment of the present inventive concept;

FIG. 12 is a cross-sectional view of a semiconductor package according to an exemplary embodiment of the present inventive concept;

FIG. 13 is a cross-sectional view of a semiconductor package according to an exemplary embodiment of the present inventive concept;

FIG. 14 is a cross-sectional view of a semiconductor package according to an exemplary embodiment of the present inventive concept;

FIG. 15 is a plan view showing elements of a semiconductor module according to an exemplary embodiment of the present inventive concept; and

FIG. 16 is a block diagram of elements of a system according to an exemplary embodiment of the present inventive concept.

### DETAILED DESCRIPTION OF THE EMBODIMENTS

Exemplary embodiments of the present inventive concept will be described in more detail below with reference to the accompanying drawings, in which exemplary embodiments of the present inventive concept are shown. Exemplary embodiments of the present inventive concept may, however, be embodied in many different forms and should not be construed as limited to the embodiments set forth herein.

It will be understood that when an element or layer is referred to as being “on” or “in contact with” another element or layer, it may be directly on or in contact with the other element or layer or intervening elements or layers may be present.

It will be understood that, although the terms “first,” and “second” may be used herein to describe various elements, components, regions, layers and/or sections, these elements, components, regions, layers and/or sections should not be limited by these terms.

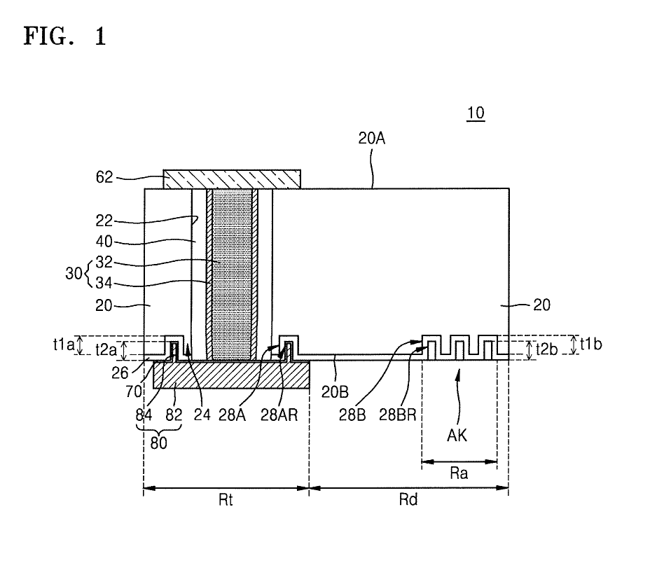

FIG. 1 is a cross-sectional view of a semiconductor chip according to an exemplary embodiment of the present inventive concept.

Referring to FIG. 1, a semiconductor chip 10 may include a semiconductor structure 20 and a through-silicon-via (TSV) structure 30 penetrating through the semiconductor structure 20 through a via hole 22 formed in the semiconductor structure 20. A via insulating layer 40 may be arranged between the semiconductor structure 20 and the TSV structure 30, and may surround a sidewall of the TSV structure 30. There may be a space 24 between the via insulating layer 40 and a protruding portion 84 of a connection pad 80.

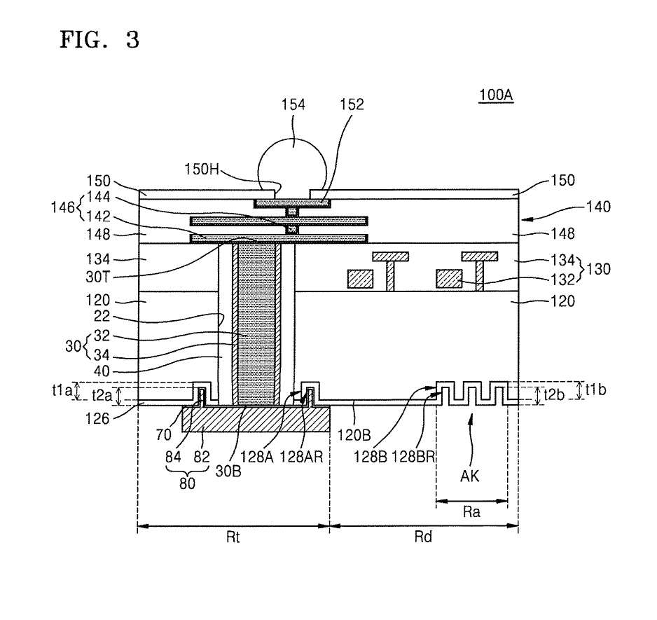

The semiconductor structure 20 may include a semiconductor substrate, an interlayer insulating layer covering an upper surface of the semiconductor substrate, and an inter-metal insulating layer covering the interlayer insulating layer. The semiconductor substrate, the interlayer insulating layer, and the inter-metal insulating layer included in the semiconductor structure 20 will be described in more detail below with reference to FIGS. 3, 4 and 5.

The TSV structure 30 may include a conductive plug 32 penetrating through the semiconductor structure 20, and a conductive barrier layer 34 surrounding the conductive plug 32. The conductive plug 32 may be a cylinder and the conductive barrier layer 34 may also be a cylinder surrounding a sidewall of the conductive plug 32.

The conductive plug 32 of the TSV structure 30 may include Cu, CuSn, CuMg, CuNi, CuZn, CuPd, CuAu, CuRe, CuW, W, or a W alloy, but exemplary embodiments of the present inventive concept are not limited thereto. For example, the conductive plug 32 may include at least one of Al, Au, Be, Bi, Co, Cu, Hf, In, Mn, Mo, Ni, Pb, Pd, Pt, Rh, Re, Ru, Ta, Te, Ti, W, Zn, and Zr, and may include at least one laminate structure thereof. For example, the conductive barrier layer 34 may include at least one material selected from the group consisting of W, WN, WC, Ti, TiN, Ta, TaN, Ru, Co, Mn, WN, Ni, and NiB, but exemplary embodiments of the present inventive concept are not limited thereto.

The conductive barrier layer 34 and the conductive plug 32 may be formed by a physical vapor deposition (PVD) process or a chemical vapor deposition (CVD) process, but exemplary embodiments of the present inventive concept are not limited thereto.

The via insulating layer 40 may include an oxide layer, a nitride layer, a carbide layer, a polymer, or a combination thereof. In some exemplary embodiments of the present inventive concept, the via insulating layer 40 may be formed by a CVD process. The via insulating layer 40 may have a thickness of about 1000 Å to about 2000 Å. For example, the via insulating layer 40 may include a high aspect ratio process (HARP) oxide layer based on ozone/tetra-ethyl ortho-silicate (O₃/TEOS) formed by a sub-atmospheric CVD process.

The semiconductor structure 20 may include a semiconductor substrate, for example, a silicon substrate. The semiconductor structure 20 may include a plurality of individual devices. The TSV structure 30 may have a sidewall surrounded by the semiconductor substrate.

The semiconductor structure 20 may include a semiconductor substrate and an interlayer insulating layer covering the semiconductor substrate. The TSV structure 30 may penetrate through the semiconductor substrate and the interlayer insulating layer. The TSV structure 30 need not penetrate through the interlayer insulating layer while penetrating through the semiconductor substrate.

The semiconductor structure 20 may include a semiconductor substrate, an interlayer insulating layer covering the semiconductor substrate, and an inter-metal insulating layer covering the interlayer insulating layer. The TSV structure 30 may penetrate through the semiconductor substrate, the interlayer insulating layer, and the inter-metal insulating layer.

When the semiconductor structure 20 includes the semiconductor substrate, the interlayer insulating layer, and/or the inter-metal insulating layer, a surface on which the interlayer insulating layer and/or the inter-metal insulating layer is arranged may be referred to as a first surface 20A, and a surface on which the semiconductor substrate is arranged may be referred to as a second surface 20B. The first surface 20A and the second surface 20B of the semiconductor structure 20 may be referred to as an upper surface and a lower surface of the semiconductor structure 20, respectively.

The semiconductor structure 20 may have a TSV region Rt in which the TSV structure 30 is arranged and an element region Rd in which the individual devices are arranged. The TSV region Rt and the element region Rd may be independent regions. The individual devices in the semiconductor structure 20 may be adjacent to the first surface 20A of the semiconductor structure 20.

The second surface 20B of the semiconductor structure 20 may include first and second grooves 28A and 28B in the TSV region Rt and the element region Rd, respectively. The first groove 28A may be spaced apart from the TSV structure 30. For example, the first groove 28A may be spaced apart from the via insulating layer 40 surrounding the sidewall of the TSV structure 30. A part of the semiconductor structure 20 may be arranged between the first groove 28A and the via insulating layer 40. A portion of the element region Rd, in which the second groove 28B is formed, may be referred to as a chip alignment region Ra. The chip alignment region Ra may be in any part of the element region Rd in the second surface 20B of the semiconductor structure 20.

The first and second grooves 28A and 28B may have first and second depths t1a and t1b with respect to the second surface 20B of the semiconductor structure 20, respectively. The first and second grooves 28A and 28B may be substantially simultaneously formed by an etching process. Thus, the first depth t1a of the first groove 28A may be substantially the same depth as the second depth t1b of the second groove 28B.

An upper pad 62 may be disposed on the first surface 20A of the semiconductor structure 20 and may be connected to one end of the TSV structure 30. The connection pad 80 may be disposed on the second surface 20B of the semiconductor structure 20 and may be connected to the other end of the TSV structure 30.

The upper pad 62 and the connection pad 80 may include metal, respectively. For example, the upper pad 62 may include Al or Cu, but exemplary embodiments of the present inventive concept are not limited thereto.

A lower insulating layer 26 may be disposed on the second surface 20B of the semiconductor structure 20 and may cover a part of the second surface 20B of the semiconductor structure 20, and thus, may expose the other end of the TSV structure 30. The lower insulating layer 26 may expose the via insulating layer 40 surrounding the other end of the TSV structure 30. The lower insulating layer 26 may cover the inner surface of the first and second grooves 28A and 28B and may define first and second recesses 28AR and 28BR in the first and second grooves 28A and 28B, respectively. The first and second recesses 28AR and 28BR may have third and fourth depths t2a and t2b with respect to the lower surface of the lower insulating layer 26, respectively. When the first depth t1a of the first groove 28A is substantially the same depth as the second depth t1b of the second groove 28B, the third depth t2a of the first recess 28AR may also be substantially the same depth as the fourth depth t2b of the second recess 28BR, but exemplary embodiments of the present inventive concept are not limited thereto. For example, when the width of the first groove 28A is different from that of the second groove 28B, the third depth t2a may be different from the fourth depth t2b even if the first depth t1a is substantially the same depth as the second depth t1b.

The lower insulating layer 26 may include a silicon oxide film, a silicon nitride film, a polymer, or a combination thereof. For example, the lower insulating layer 26 may have a multi-layered structure in which a silicon nitride film is arranged between silicon oxide films. A level of the lower surface of the lower insulating layer 26 may be substantially the same as that of the other end of the TSV structure 30.

A seed layer 70 may be disposed between the connection pad 80 and the semiconductor structure 20. The seed layer 70 may include films of various compositions according to component materials of the connection pad 80. The seed layer 70 may include, for example, Cu, Cu alloy, Co, Ni, Ru, Co/Cu, or Ru/Cu.

The connection pad 80 may include a conductive pad, a solder ball, a solder bump, or a redistribution conductive layer. The connection pad 80 may be connected to the other end of the TSV structure 30, and may have a foundation base 82 disposed on the second surface 20B of the semiconductor structure 20 and the protruding portion 84 which protrudes from the foundation base 82 and may extend to the inside of the first groove 28A formed on the second surface 20B of the semiconductor structure 20. The protruding portion 84 may fill the first recess 28AR.

The foundation base 82 and the protruding portion 84 may be integrally formed. The foundation base 82 may be a portion which has a plate structure and is disposed below the other end of the TSV structure 30, and the protruding portion 84 may be a portion which protrudes from the foundation base 82 and extends over the other end of the TSV structure 30.

The protruding portion 84 may be spaced apart from the TSV structure 30. For example, the protruding portion 84 may be spaced apart from the via insulating layer 40 surrounding the sidewall of the TSV structure 30, and a part of the semiconductor structure 20 may be arranged between the protruding portion 84 and the TSV structure 30, or between the protruding portion 84 and the via insulating layer 40.

The connection pad 80 may include Ni, Cu, Al, Au, W, or a combination thereof, but exemplary embodiments of the present inventive concept are not limited thereto.

FIG. 1 illustrates an exemplary embodiment of the present inventive concept in which the seed layer 70 and the connection pad 80 have separate configurations and in which the seed layer 70 and the connection pad 80 are separately formed due to a manufacturing method. Thus, the seed layer 70 and the connection pad 80 may function together as a connection pad connected to the other end of the TSV structure 30. Thus, both the protruding portion 84 of connection pad 80 and the seed layer 70 covering the surface of the protruding portion 84 may be referred to as a protruding portion of the connection pad and both the foundation base 82 of the connection pad 80 and the seed layer 70 covering the surface of the foundation base 82 may be referred to as a foundation base of the connection pad.

The second groove 28B, or the second groove 28B and the second recess 28BR may form a chip alignment mark AK on the lower surface of the semiconductor structure 20. The chip alignment mark AK may be used for an alignment of the semiconductor chips 10 when laminating a plurality of the semiconductor chips 10 to be electrically connected through the TSV structure 30.

In a general manufacturing process of a semiconductor chip, an alignment mark formed in a scribe lane of a semiconductor wafer may be removed during a dicing process of cutting the semiconductor wafer along the scribe lane to separate the semiconductor wafer from the semiconductor chip. Alternatively, the alignment mark may be formed on the upper surface of a semiconductor structure even if a part of the alignment mark remains as a part of the scribe lane remains on the edge of the diced semiconductor chip.

The chip alignment mark AK according to an exemplary embodiment of the present inventive concept may be formed on the lower surface of the semiconductor structure 20 in the semiconductor chip 10 since the chip alignment mark AK may be used for the alignment of a plurality of the semiconductor chips 10 during a laminating process of the semiconductor chips 10. The chip alignment mark AK may be formed in the chip alignment region Ra, which may be a part of the element region Rd. The chip alignment mark AK may be formed in the second surface 20B of the semiconductor structure 20.

In the semiconductor chip 10 according to an exemplary embodiment of the present inventive concept, the connection pad 80 connected to the TSV structure 30 may include the protruding portion 84. Thus, an adhesive strength between the connection pad 80 and the semiconductor structure 20 may be increased due to increasing a contact area between the semiconductor structure 20 and the connection pad 80 due to the protruding portion 84. It may be possible to stabilize a connection structure between the TSV structure 30 and the connection pad 80. Thus, cracks, which may be generated by shear stress between the semiconductor structure 20 and the connection pad 80, may be reduced or eliminated by the protruding portion 84, and thus contact reliability may be increased.

The first and second grooves 28A and 28B forming the protruding portion 84 and the chip alignment mark AK may be substantially simultaneously formed by an etching process. Thus, a manufacturing cost of the semiconductor chip 10 may be reduced since a separate process for forming the protruding portion 84 might not be performed.

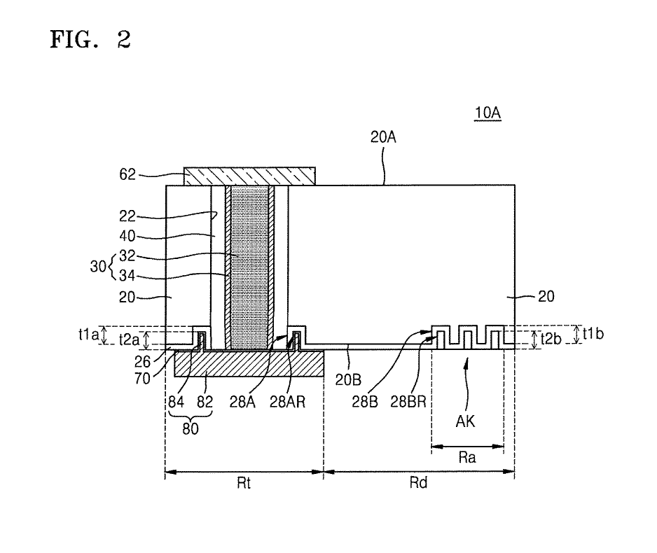

FIG. 2 is a cross-sectional view of a semiconductor chip according to another exemplary embodiment of the present inventive concept. In FIG. 2, like reference numerals as those of FIG. 1 may refer to the same elements, and duplicative descriptions may be omitted.

Referring to FIG. 2, a semiconductor chip 10A may include the semiconductor structure 20 and the TSV structure 30 penetrating through the semiconductor structure 20 through the via hole 22 formed in the semiconductor structure 20. The via insulating layer 40 may be arranged between the semiconductor structure 20 and the TSV structure 30, and may surround a sidewall of the TSV structure 30.

The second surface 20B of the semiconductor structure 20 may include first and second grooves 28A and 28B in the TSV region Rt and the element region Rd, respectively. The first groove 28A may be spaced apart from the TSV structure 30. For example, a part of the inner surface of the first groove 28A may be a part of a sidewall of the via insulating layer 40 surrounding a sidewall of the TSV structure 30. A part of the semiconductor structure 20 arranged between the first groove 28A and the via insulating layer 40 may be omitted.

Thus, a part of the lower insulating layer 26 and the via insulating layer 40 may be arranged between the protruding portion 84 and the TSV structure 30, and a part of the semiconductor structure 20 arranged between the protruding portion 84 and the via insulating layer 40 may be omitted.

In the semiconductor chip 10A according to an exemplary embodiment of the present inventive concept, the connection pad 80 connected to the TSV structure 30 may include the protruding portion 84. Thus, an adhesive strength between the connection pad 80 and the semiconductor structure 20 may be increased due to increasing a contact area between the semiconductor structure 20 and the connection pad 80 due to the protruding portion 84. It may be possible to stabilize a connection structure between the TSV structure 30 and the connection pad 80 as cracks, which may be generated by shear stress between the semiconductor structure 20 and the connection pad 80, may be reduced or prevented by the protruding portion 84, and thus contact reliability may be increased.

The first and second grooves 28A and 28B forming the protruding portion 84 and the chip alignment mark AK may be substantially simultaneously formed by an etching process. Thus, a manufacturing cost of the semiconductor chip 10A may be reduced since a separate process for forming the protruding portion 84 might not be performed.

FIG. 3 is a cross-sectional view of a semiconductor chip according to another exemplary embodiment of the present inventive concept. In FIG. 3, like reference numerals as those of FIG. 1 may refer to the same elements, and duplicative descriptions may be omitted.

Referring to FIG. 3, a semiconductor chip 100A may include a semiconductor substrate 120, a front-end-of-line (FEOL) structure 130, and a back-end-of-line (BEOL) structure 140. The TSV structure 30 may be disposed in the via hole 22 that may penetrate through the semiconductor substrate 120 and the FEOL structure 130. The via insulating layer 40 may be arranged between the semiconductor substrate 120 and the TSV structure 30, and between the FEOL structure 130 and the TSV structure 30.

The TSV structure 30 may include the conductive plug 32 penetrating through the semiconductor substrate 120 and the FEOL structure 130, and the conductive barrier layer 34 surrounding the conductive plug 32.

The semiconductor substrate 120 may be a semiconductor wafer. For example, the semiconductor substrate 120 may include silicon (Si). For example, the semiconductor substrate 120 may include a semiconductor material such as germanium (Ge), or a compound semiconductor material such as silicon carbide (SiC), gallium arsenide (GaAs), indium arsenide (InAs), and indium phosphide (InP). For example, the semiconductor substrate 120 may have a silicon on insulator (SOI) structure. For example, the semiconductor substrate 120 may include a buried oxide (BOX) layer. The semiconductor substrate 120 may include a conductive region, for example, a well doped with impurities or a structure doped with impurities. The semiconductor substrate 120 may include various device isolation structures such as a shallow trench isolation (STI) structure.

A lower surface 120B of the semiconductor substrate 120 may form first and second grooves 128A and 128B in the TSV region Rt and the element region Rd, respectively. The first groove 128A may be spaced apart from the TSV structure 30. For example, the first groove 128A may be spaced apart from the via insulating layer 40 surrounding the sidewall of the TSV structure 30. A part of the semiconductor substrate 120 may be arranged between the first groove 128A and the via insulating layer 40. A portion of the element region Rd, in which the second groove 128B is formed, may be referred to as a chip alignment region Ra. The chip alignment region Ra may be in any part of the element region Rd in the lower surface 120B of the semiconductor substrate 120.

The first and second grooves 128A and 128B may have first and second depths t1a and t1b with respect to the lower surface 120B of the semiconductor substrate 120, respectively. The first and second grooves 128A and 128B may be substantially simultaneously formed by an etching process. Thus, the first depth t1a of the first groove 128A may be substantially the same depth as the second depth t1b of the second groove 128B.

The lower surface 120B of the semiconductor substrate 120 may be covered by a lower insulating layer 126. The lower insulating layer 126 may include, for example, a silicon oxide film, a silicon nitride film, a polymer, or a combination thereof. The lower insulating layer 126 may expose the via insulating layer 40 surrounding the other end of the TSV structure 30. The lower insulating layer 126 may cover the inner surface of the first and second grooves 128A and 128B and may define first and second recesses 128AR and 128BR in the first and second grooves 128A and 128B, respectively. The first and second recesses 128AR and 128BR may have third and fourth depths t2a and t2b with respect to the lower surface of the lower insulating layer 126, respectively.

The second groove 128B, or the second groove 128B and the second recess 128BR may form the chip alignment mark AK on the lower surface 120B of the semiconductor structure 120. The chip alignment mark AK may be used for an alignment of the semiconductor chips 100A when laminating a plurality of the semiconductor chips 100A to be electrically connected through the TSV structure 30. The chip alignment mark AK may be formed in the chip alignment region Ra that is a part of the element region Rd.

The FEOL structure 130 may include a plurality of individual devices 132 and an interlayer insulating layer 134. The plurality of individual devices 132 may be arranged in the element region Rd. The plurality of individual devices 132 may include various microelectronic devices, for example, a metal-oxide-semiconductor field effect transistor (MOSFET), system large scale integration (LSI), an image sensor such as a complementary MOS imaging sensor (CIS), a micro-electro-mechanical system (MEMS), an active device, and a passive device. The plurality of individual devices 132 may be electrically connected to the conductive region of the semiconductor substrate 120. The plurality of individual devices 132 may be electrically isolated from other adjacent individual devices by the interlayer insulating layer 134, and may be respectively electrically connected to the adjacent individual devices by a conductive line and a contact plug.

The BEOL structure 140 may have a multi-layered wiring structure 146 including a plurality of metal wiring layers 142 and a plurality of contact plugs 144. The multi-layered wiring structure 146 may be connected to the TSV structure 30.

The BEOL structure 140 may include other multi-layered wiring structures, each including a plurality of metal wiring layers and a plurality of contact plugs, on another region of the semiconductor substrate 120. The BEOL structure 140 may include the plurality of wiring structures connecting the individual devices included in the FEOL structure 130 to other wires. The multi-layered wiring structures 146 and the other multi-layered wiring structures included in the BEOL structure 140 may be insulated from each other by an inter-metal insulating layer 148. The BEOL structure 140 may include a seal ring protecting the plurality of wiring structures and other structures under the wiring structures from external shock or moisture.

An upper surface 30T of the TSV structure 30 that penetrates through the semiconductor substrate 120 and the FEOL structure 130 may be connected to the metal wiring layer 142 of the multi-layered wiring structure 146 included in the BEOL structure 140. The upper pad 62 illustrated, for example, in FIG. 1 may correspond to the metal wiring layer 142 or the bonding pad 152.

An upper insulating layer 150 may be disposed on the inter-metal insulating layer 148. The upper insulating layer 150 may include a silicon oxide layer, a silicon nitride layer, a polymer, or a combination thereof. A hole 150H exposing a bonding pad 152 connected to the multi-layered wiring structure 146 may be formed in the upper insulating layer 150. The bonding pad 152 may be connected to a connection terminal 154 via the hole 150H.

A bottom surface 30B of the TSV structure 30 may be covered by the seed layer 70. The connection pad 80 may be connected to the TSV structure 30 via the seed layer 70.

The connection pad 80 may be connected to the other end of the TSV structure 30 and may include the foundation base 82 disposed on the lower surface 120B of the semiconductor substrate 120 and the protruding portion 84 which protrudes from the foundation base 82 and extends to the inside of the first groove 128A formed in the lower surface 120B of the semiconductor substrate 120. The protruding portion 84 may fill the first recess 128AR. The protruding portion 84 may be spaced apart from the TSV structure 30. For example, the protruding portion 84 may be spaced apart from the via insulating layer 40 surrounding the sidewall of the TSV structure 30, and a part of the semiconductor substrate 120 may be arranged between the protruding portion 84 and the TSV structure 30, or between the protruding portion 84 and the via insulating layer 40.

The connection terminal 154 and the connection pad 80 are not limited to the exemplary embodiment of the present inventive concept illustrated in FIG. 3, and may each include a conductive pad, a solder ball, a solder bump, or a redistribution conductive layer. In some exemplary embodiments of the present inventive concept, the connection terminal 154 may be omitted from the semiconductor chip 100A.

Each forming process of the BEOL structure 140, the connection terminal 154, the seed layer 70, and the connection pad 80 may be performed after forming the TSV structure 30.

In the semiconductor chip 100A according to an exemplary embodiment of the present inventive concept, the connection pad 80 connected to the TSV structure 30 may include the protruding portion 84. Thus, an adhesive strength between the connection pad 80 and the semiconductor substrate 120 may be increased due to increasing a contact area between the semiconductor substrate 120 and the connection pad 80 due to the protruding portion 84. Thus, it may be possible to stabilize a connection structure between the TSV structure 30 and the connection pad 80 as cracks, which may be generated by shear stress between the semiconductor substrate 120 and the connection pad 80, may be reduced or eliminated by the protruding portion 84, and thus contact reliability may be increased.

The first and second grooves 128A and 128B forming the protruding portion 84 and the chip alignment mark AK may be substantially simultaneously formed by an etching process. Thus, a manufacturing cost of the semiconductor chip 100A may be reduced since a separate process for forming the protruding portion 84 might not be performed.

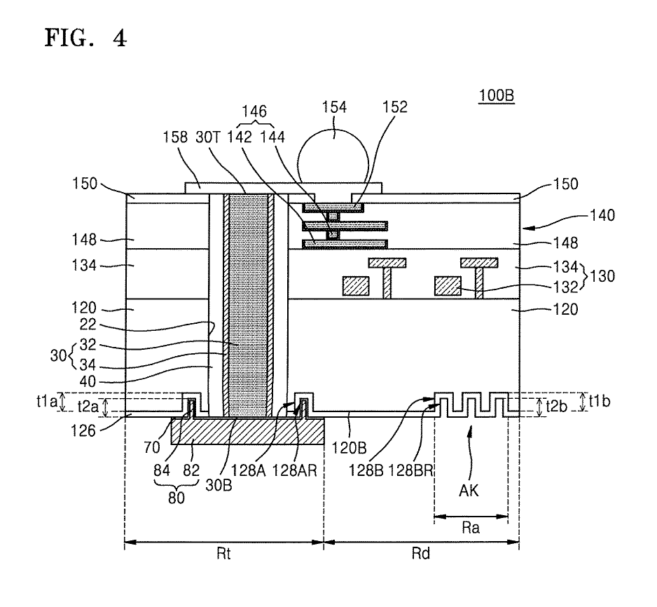

FIG. 4 is a cross-sectional view of a semiconductor chip according to another exemplary embodiment of the present inventive concept. In FIG. 4, like reference numerals as those of FIGS. 1 and 3 may refer to the same elements, and duplicative descriptions may be omitted.

Referring to FIG. 4, in a semiconductor chip 100B, the TSV structure 30 may be formed after the FEOL structure 130 and the BEOL structure 140 are formed. Thus, the TSV structure 30 may penetrate through the semiconductor substrate 120, the interlayer insulating layer 134 of the FEOL structure 130, and the inter-metal insulating layer 148 of the BEOL structure 140. The conductive barrier layer 34 of the TSV structure 30 may include a first outer wall portion surrounded by the semiconductor substrate 120, a second outer wall portion surrounded by the interlayer insulating layer 134, and a third outer wall portion surrounded by the inter-metal insulating layer 148.

An upper wire 158 may extend between the TSV structure 30 and the connection terminal 154 on the BEOL structure 140 to electrically connect the TSV structure 30 and the connection terminal 154 to each other. The TSV structure 30 may be connected to the upper wire 158 after penetrating through the upper insulating layer 150, and may be connected to the connection terminal 154 via the upper wire 158.

The bottom surface 30B of the TSV structure 30 may be covered by the seed layer 70. The connection pad 80 may be connected to the TSV structure 30 via the seed layer 70.

The connection pad 80 may be connected to the other end of the TSV structure 30 and may include the foundation base 82 disposed on the lower surface 120B of the semiconductor substrate 120 and the protruding portion 84 which protrudes from the foundation base 82 and extends to the inside of the first groove 128A formed in the lower surface 120B of the semiconductor substrate 120. The protruding portion 84 may fill the first recess 128AR.

The connection terminal 154 and the connection pad 80 are not limited to the exemplary embodiment of the present inventive concept illustrated in FIG. 4, and may each include a conductive pad, a solder ball, a solder bump, or a redistribution conductive layer. In some exemplary embodiments of the present inventive concept, the connection terminal 154 may be omitted from the semiconductor chip 100B.

Each forming process of the connection terminal 154, the seed layer 70, and the connection pad 80 may be performed after forming the TSV structure 30.

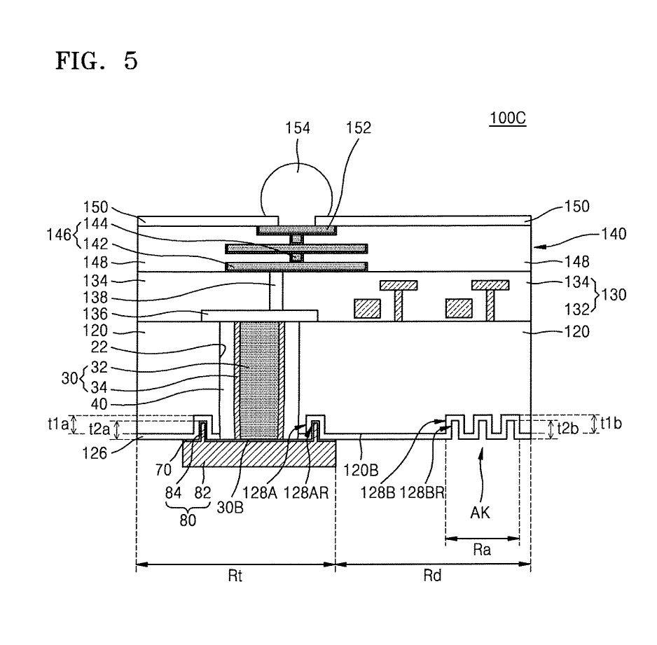

FIG. 5 is a cross-sectional view of a semiconductor chip according to another exemplary embodiment of the present inventive concept. In FIG. 5, like reference numerals as those of FIGS. 1, 3 and 4 may refer to the same elements, and duplicative descriptions may be omitted.

In a semiconductor chip 100C, the TSV structure 30 may extend through the semiconductor substrate 120. After forming the TSV structure 30, the FEOL structure 130 and the BEOL structure 140 may be formed on the TSV structure 30 and the semiconductor substrate 120. The TSV structure 30 may be connected to the multi-layered wiring structure 146 of the BEOL structure 140 via a conductive line 136 and a contact plug 138 included in the FEOL structure 130.

The bottom surface 30B of the TSV structure 30 may be covered by the seed layer 70. The connection pad 80 may be connected to the TSV structure 30 via the seed layer 70.

The connection pad 80 may be connected to the other end of the TSV structure 30 and may include the foundation base 82 disposed on the lower surface 120B of the semiconductor substrate 120 and the protruding portion 84 which protrudes from the foundation base 82 and may extend to the inside of the first groove 128A formed in the lower surface 120B of the semiconductor substrate 120. The protruding portion 84 may fill the first recess 128AR.

The connection terminal 154 and the connection pad 80 are not limited to the examples shown in FIG. 5, and may each include a conductive pad, a solder ball, a solder bump, or a redistribution conductive layer. In some exemplary embodiments of the present inventive concept, the connection terminal 154 may be omitted from the semiconductor chip 100C.

Each forming process of the connection terminal 154, the seed layer 70, and the connection pad 80 may be performed after forming the BEOL structure 140.

In the semiconductor chips 100A, 100B, and 100C shown in FIGS. 3, 4 and 5, the connection pad 80 has the same shape as the connection pad 80 illustrated in FIG. 1, but exemplary embodiments of the present inventive concept are not limited thereto. The connection pad 80 of the semiconductor chips 100A, 100B, and 100C may have the same shape as the connection pad 80 illustrated in FIG. 2. A part of the lower insulating layer 126 and the via insulating layer 40 may be arranged between the protruding portion 84 and the TSV structure 30, and a part of the semiconductor substrate 120 need not be arranged between the protruding portion 84 and the via insulating layer 40.

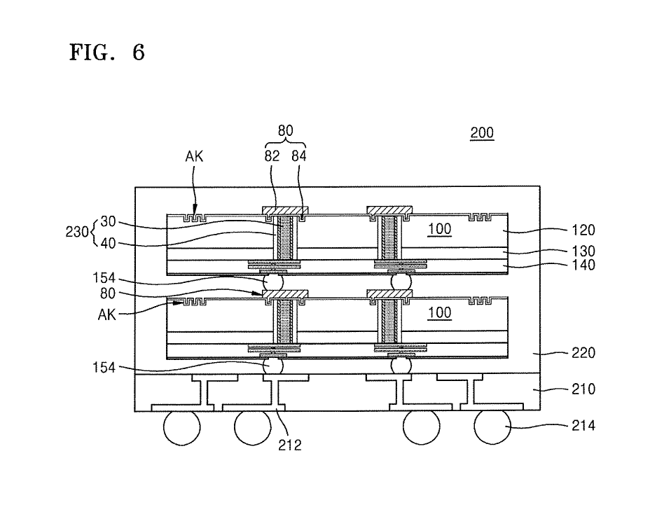

FIG. 6 is a cross-sectional view illustrating a schematic configuration of a semiconductor package according to an exemplary embodiment of the present inventive concept. In FIG. 6, like reference numerals as those of FIGS. 1 to 5 may refer to the same elements, and duplicative descriptions may be omitted.

Referring to FIG. 6, a semiconductor package 200 may include a package substrate 210, and a plurality of semiconductor chips 100 disposed on the package substrate 210. The semiconductor chips 100 may be disposed on each other such that the chip alignment marks AK on each lower surface of the semiconductor chips 100 overlap each other.

For example, the package substrate 210 may be a printed circuit board, in which wiring structures 212 are formed.

Referring to FIG. 6, the semiconductor package 200, on which two integrated circuit devices 100 are disposed, is illustrated. However, exemplary embodiments of the present inventive concept are not limited thereto. A plurality of integrated circuit devices 100 may be disposed on the package substrate 210 in a vertical or a horizontal direction. Referring to FIG. 6, some elements of the semiconductor chip 100 may be omitted; however, the at least one semiconductor chip 100 may have at least one structure selected from the semiconductor chips 10, 100A, 100B, and 100C. In each semiconductor chip 100, the TSV structure 30 and the via insulating layer 40 surrounding the TSV structure 30 may form a TSV unit 230.

A plurality of connection terminals 214 electrically connecting the semiconductor package 200 to the outside may be disposed on the package substrate 210 and may be respectively connected to the internal wiring structures 212. For example, the plurality of connection terminals 214 may be solder balls, but exemplary embodiments of the present inventive concept are not limited thereto.

The electric connection between the package substrate 210 and the semiconductor chip 100 or electric connection between two adjacent integrated circuit devices 100 may be formed by using the TSV structure 30, the connection terminal 154, the seed layer 70, and the connection pad 80 in the semiconductor chip 100.

Referring to FIG. 6, two integrated circuit devices 100 may be disposed in a vertical direction on the package substrate 210 and the two integrated circuit devices 100 may be electrically connected together in the semiconductor package 200. The connection pad 80 in the lower semiconductor chip 100 may include the protruding portion 84. Thus, an adhesive strength between the connection pad 80 and the semiconductor substrate 120 may be increased due to increasing a contact area between the semiconductor substrate 120 and the connection pad 80 due to the protruding portion 84. Thus, it may be possible to stabilize a connection structure between the TSV structure 30 and the connection pad 80 as cracks, which may be generated by shear stress between the semiconductor substrate 120 and the connection pad 80, may be reduced or prevented by the protruding portion 84, and thus contact reliability may be increased.

The first and second grooves 128A and 128B forming the protruding portion 84 and the chip alignment mark AK may be substantially simultaneously formed by an etching process. Thus, a manufacturing cost of the semiconductor chip 100 may be reduced since a separate process for forming the protruding portion 84 might not be performed.

The semiconductor package 200 may include a molding layer 220 molding the plurality of semiconductor chips 100. The molding layer 220 may include a polymer, for example, an epoxy molding compound (EMC).

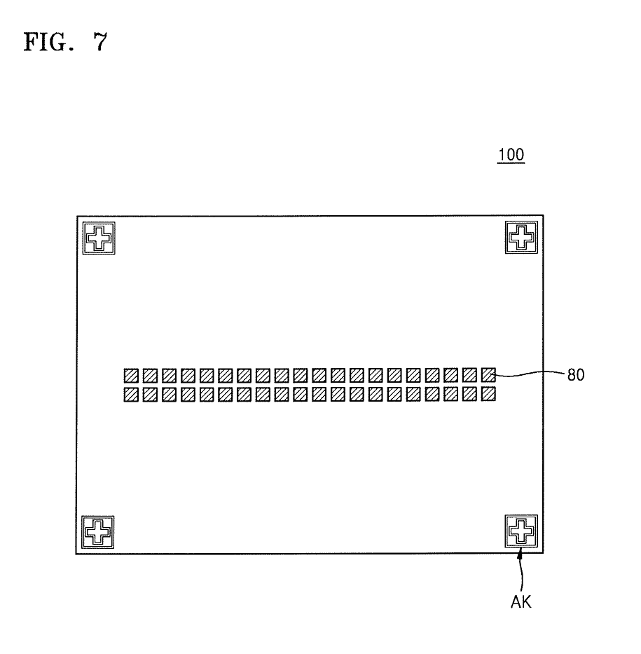

FIG. 7 is a plan view illustrating a rear surface of a semiconductor chip according to an exemplary embodiment of the present inventive concept.

Referring to FIG. 7, a plurality of connection pads 80 and chip alignment marks AK may be arranged on the rear surface of the semiconductor chip 100. The connection pads 80 may be arranged in a center part of the rear surface of the semiconductor chip 100 by a center pad method, and the chip alignment marks AK may be arranged in an edge part of the rear surface of the semiconductor chip 100, but exemplary embodiments of the present inventive concept are not limited thereto. For example, the connection pads 80 may be arranged in the edge part of the rear surface of the semiconductor chip 100 by an edge pad method, and the chip alignment marks AK may be arranged in the other part of the rear surface of the semiconductor chip 100.

At least hundreds or thousands of the connection pads 80 may be arranged on the rear surface of the semiconductor chip 100 corresponding to the number of TSV structures 30. The connection pads 80 shown in FIG. 7 have rectangular planar shapes, but exemplary embodiments of the present inventive concept are not limited thereto. The shape of the connection pads 80 may vary and may include a circular shape or a polygonal shape.

For example, the chip alignment marks AK may be arranged in at least four areas. Planar shapes of the chip alignment marks AK shown in FIG. 7 are examples and exemplary embodiments of the present inventive concept are not limited thereto. The shapes used for an alignment of the semiconductor chip 100 may be any desired shape.

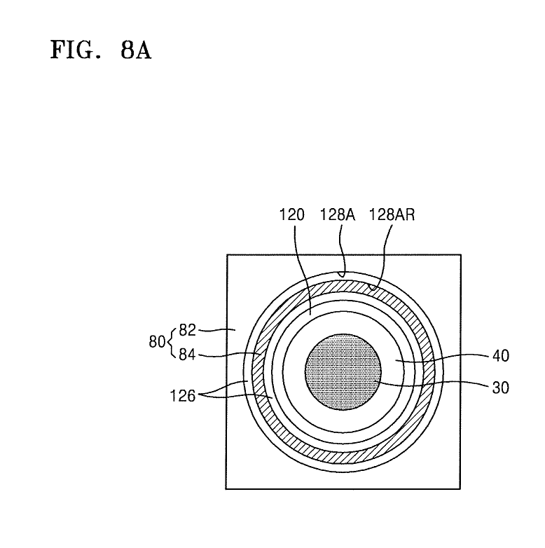

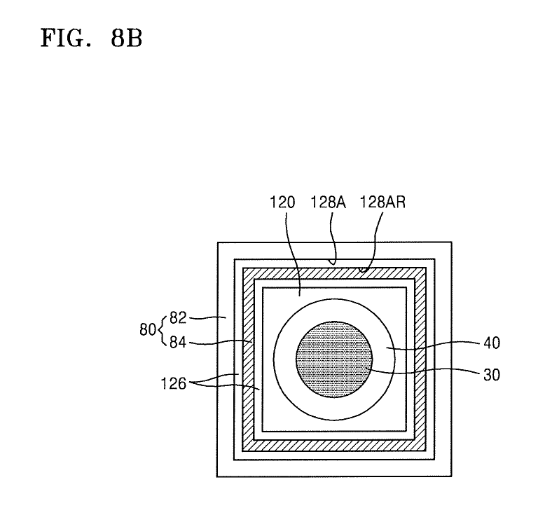

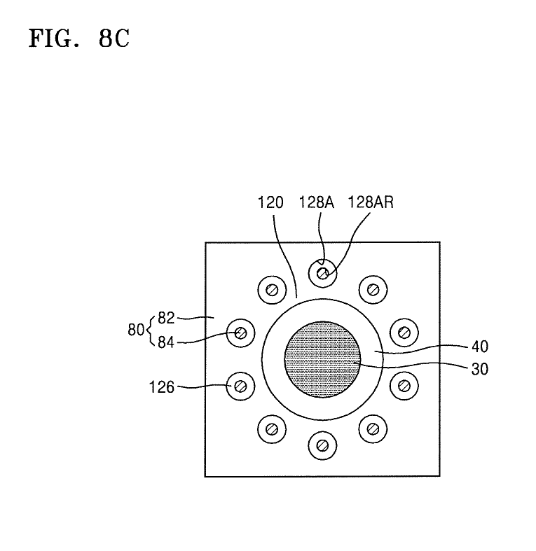

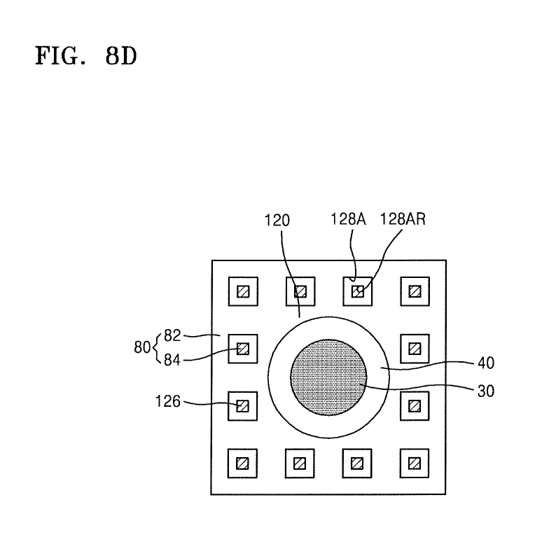

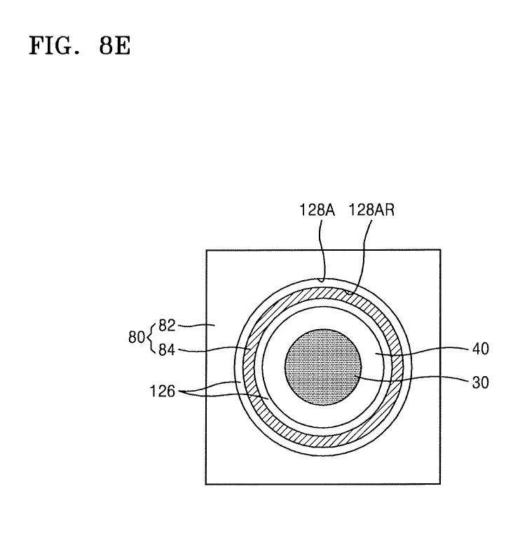

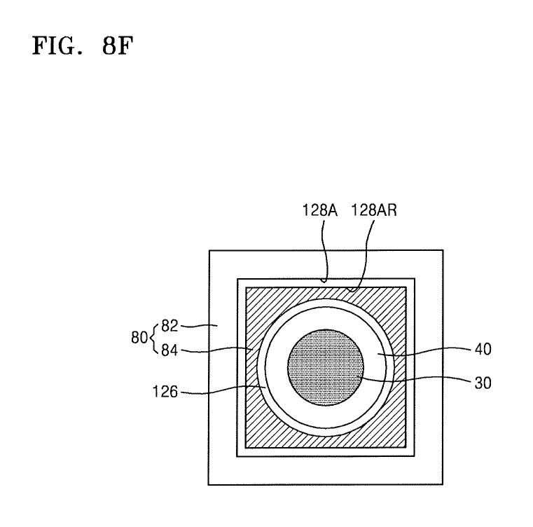

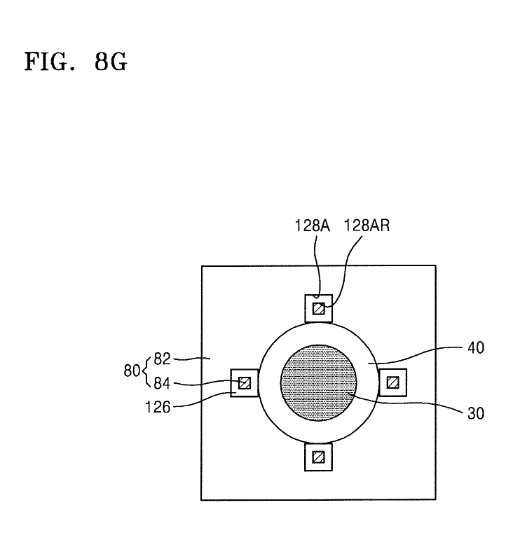

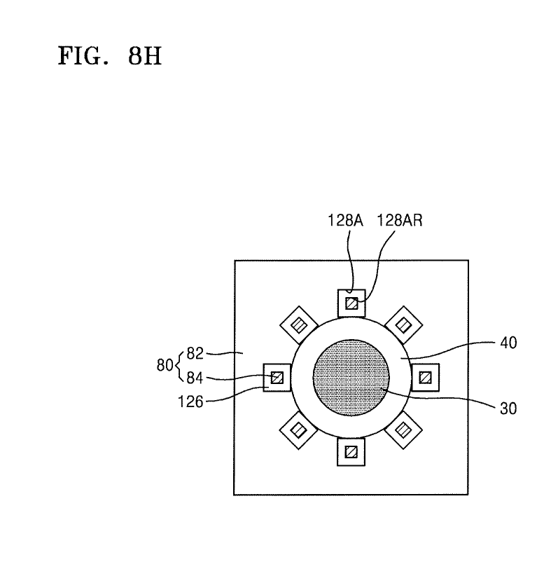

FIGS. 8A through 8H are plan views illustrating a configuration of a connection pad included in a semiconductor chip and a semiconductor package, according to an exemplary embodiment of the present inventive concept.

Referring to FIGS. 8A through 8H, the connection pad 80 may include the foundation base 82 and the protruding portion 84.

Referring to FIGS. 8A to 8D, the first groove 128A may be spaced apart from a TSV structure 30. For example, the first groove 128A may be spaced apart from the via insulating layer 40 surrounding a sidewall of the TSV structure 30, and a part of a semiconductor substrate 120 may be arranged between the first groove 128A and the via insulating layer 40.

Referring to FIGS. 8A and 8B, the first recess 128AR and the protruding portion 84 filling the first recess 128AR may surround the periphery of the TSV structure 30. Since the protruding portion 84 is formed in the lower surface 120B of the semiconductor substrate 120, the protruding portion 84 may surround the periphery of a sidewall of one end portion of the lower surface 120B side of the semiconductor substrate 120 in the TSV structure 30.

Referring to FIG. 8A, the first recess 128AR and the protruding portion 84 filling the first recess 128AR may have a circular ring shape surrounding the periphery of the TSV structure 30. Referring to FIG. 8B, the first recess 128AR and the protruding portion 84 filling the first recess 128AR may have a square ring shape surrounding the periphery of the TSV structure 30.

Referring to FIGS. 8C and 8D, a plurality of the first recesses 128AR and a plurality of the protruding portion 84 may fill a plurality of the first recess 128AR and may be spaced apart from each other along the periphery of the TSV structure 30. The protruding portion 84 is disposed in the lower surface 120B of the semiconductor substrate 120, and thus a plurality of the protruding portions 84 may be spaced apart from each other along the periphery of the sidewall of one end portion of the lower surface 120B of the semiconductor substrate 120 in the TSV structure 30.

Referring to FIG. 8C, a plurality of circular ring-shaped first recesses 128AR and a plurality of protruding portions 84 respectively filling the plurality of first recesses 128AR may be spaced apart from each other along the periphery of the TSV structure 30. Referring to FIG. 8D, the plurality of square ring-shaped first recesses 128AR and the plurality of protruding portions 84 respectively filling the plurality of first recesses 128AR may be spaced apart from each other along the periphery of the TSV structure 30.

Referring to FIGS. 8E to 8H, the first groove 128A may be spaced apart from the TSV structure 30. A part of an inner surface of the first groove 128A may be a part of a sidewall of the via insulating layer 40 surrounding a sidewall of the TSV structure 30. A part of the semiconductor structure 120 shown in FIGS. 8A to 8D need not be arranged between the first groove 128A and the via insulating layer 40.

Referring to FIGS. 8E and 8F, the first recess 128AR and the protruding portion 84 filling the first recess 128AR may surround the periphery of the TSV structure 30. Since the protruding portion 84 may be disposed in the lower surface 120B of the semiconductor substrate 120, the protruding portion 84 may surround the periphery of a sidewall of one end portion of the lower surface 120B of the semiconductor substrate 120 in the TSV structure 30.

Referring to FIG. 8E, the first recess 128AR and the protruding portion 84 filling the first recess 128AR may have a circular ring shape surrounding the periphery of the TSV structure 30. Referring to FIG. 8F, the first recess 128AR and the protruding portion 84 filling the first recess 128AR may surround the periphery of the TSV structure 30, wherein the outer edge may have a square shape and the inner edge may have a circular shape.

Referring to FIGS. 8G and 8H, a plurality of the first recesses 128AR and a plurality of the protruding portions 84 filling the first recesses 128AR may be spaced apart from each other along the periphery of the TSV structure 30. The plurality of first recesses 128AR and the plurality of protruding portions 84 may have square-shapes, but exemplary embodiments of the present inventive concept are not limited thereto. For example, the plurality of first recesses 128AR and the plurality of protruding portions 84 may have circular shapes.

The plurality of protruding portions 84 may be spaced apart from each other along the periphery of the sidewall of one end portion of the lower surface 120B side of the semiconductor substrate 120 in the TSV structure 30.

FIGS. 8G and 8H illustrate four or eight of the first recesses 128AR, respectively, but exemplary embodiments of the present inventive concept are not limited thereto. For example, the number of the first recesses 128AR and protruding portions 84 may vary and may include two, three, five, seven, nine or more.

The connection pads 80 of the semiconductor chips 10, 10A, 100A, 100B, 100C, and 100 may have the same shape as at least one of the connection pads 80 shown in FIGS. 8A through 8H, but exemplary embodiments of the present inventive concept are not limited thereto. The protruding portions 84 of the connection pads 80 may have a variety of shapes in which the protruding portions 84 extend from the foundation base 82 to the semiconductor structure 20 or the semiconductor substrate 120.

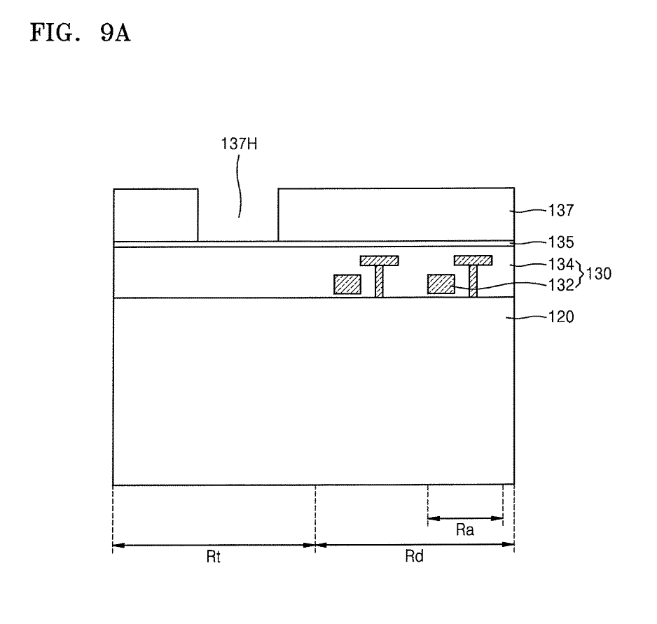

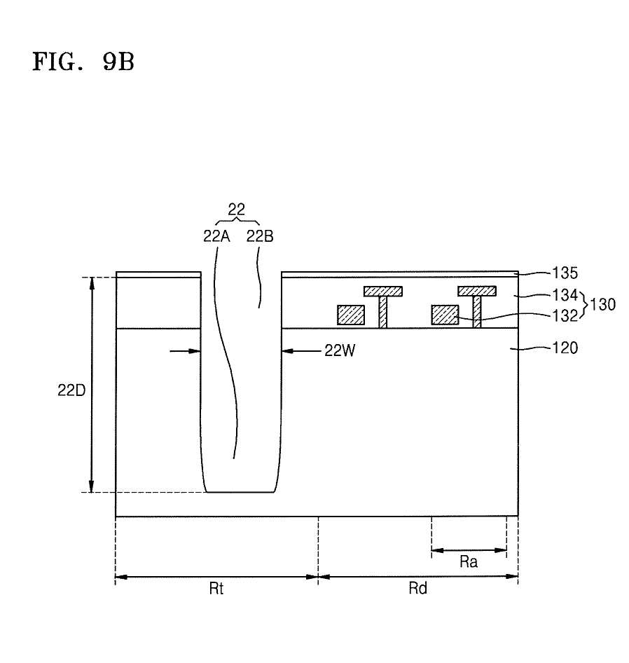

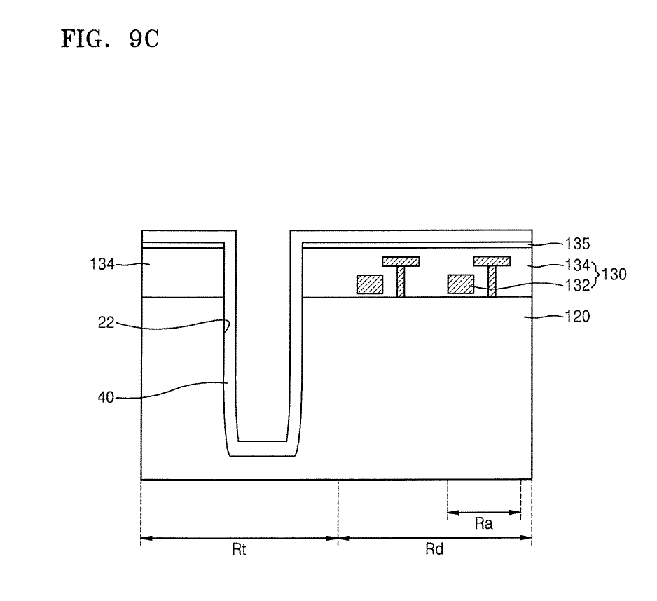

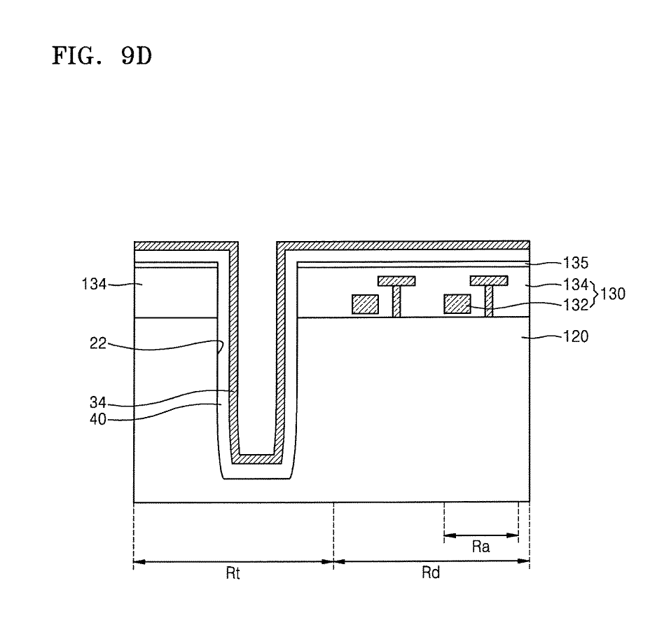

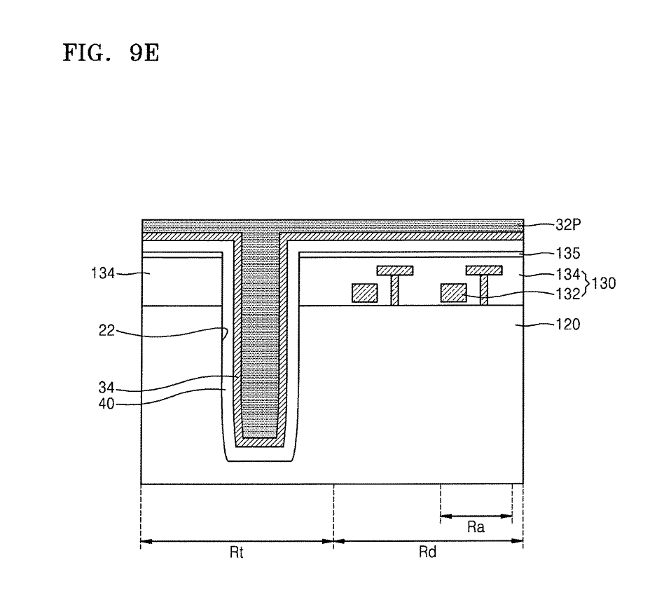

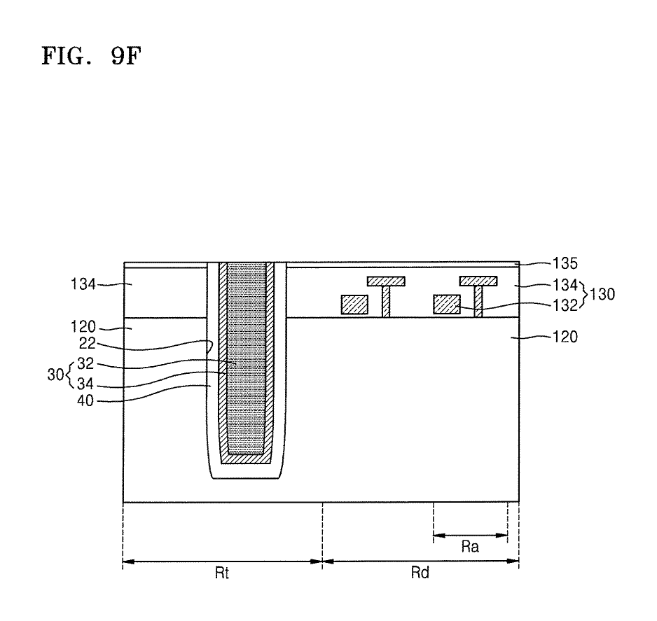

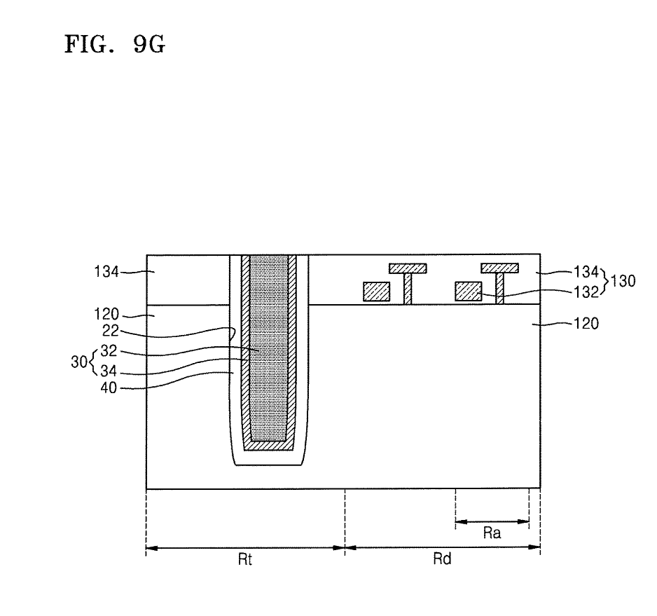

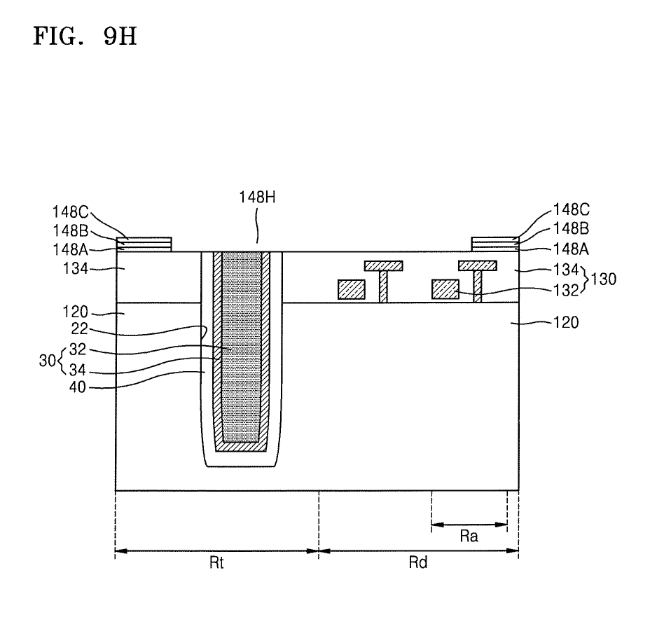

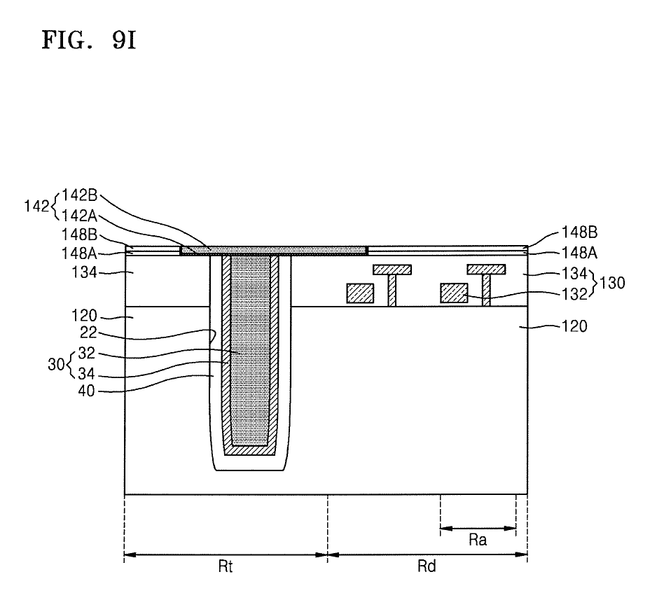

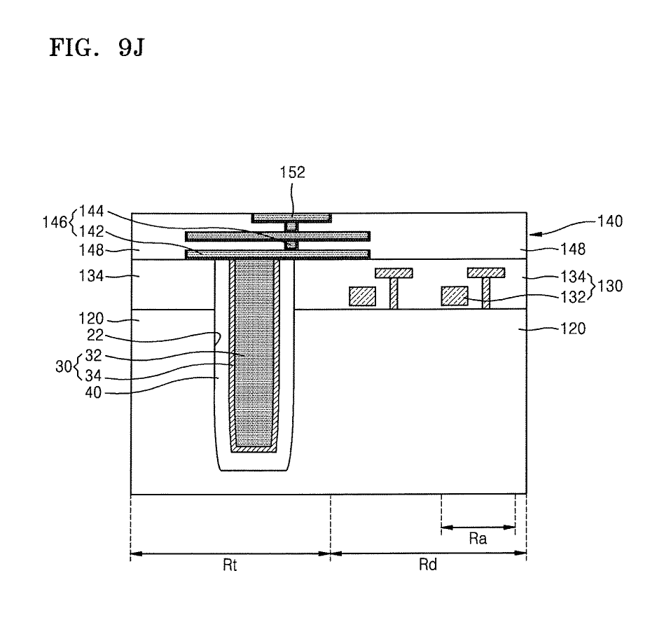

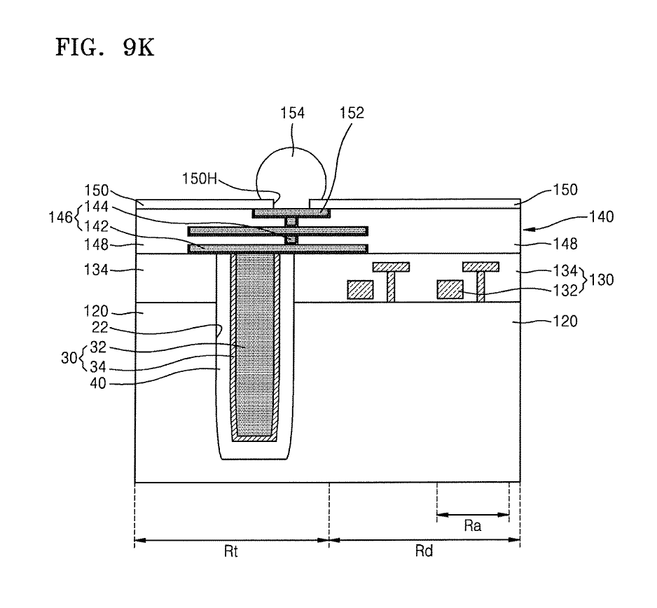

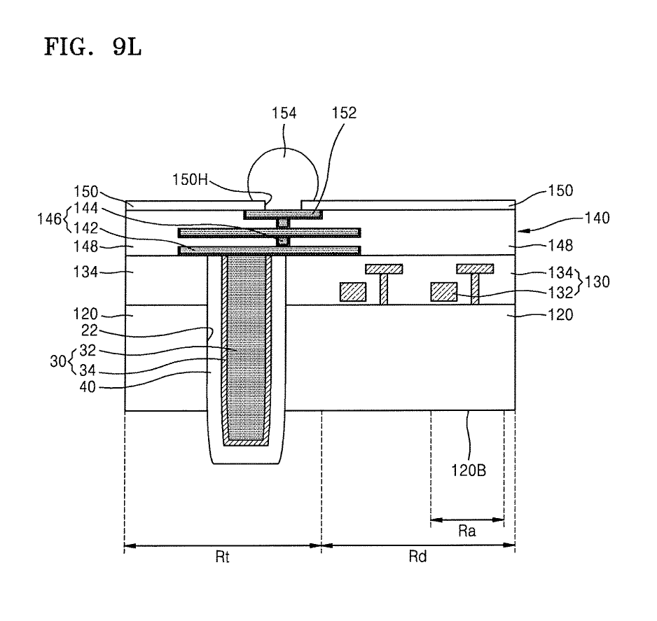

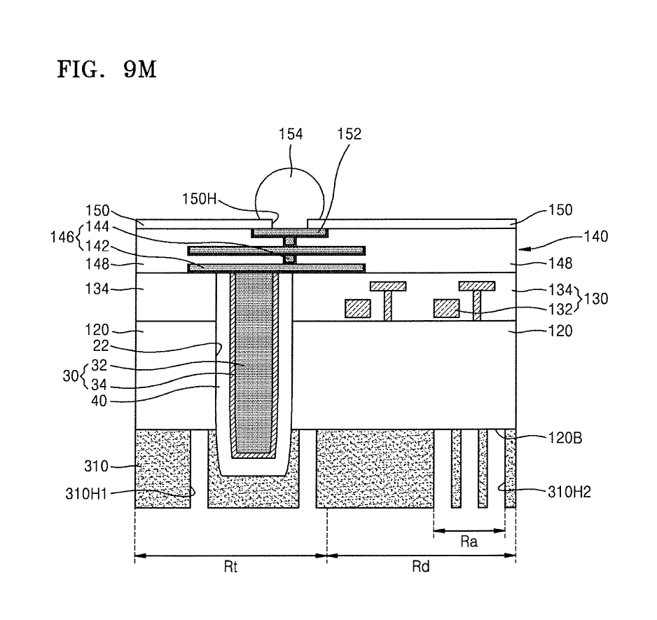

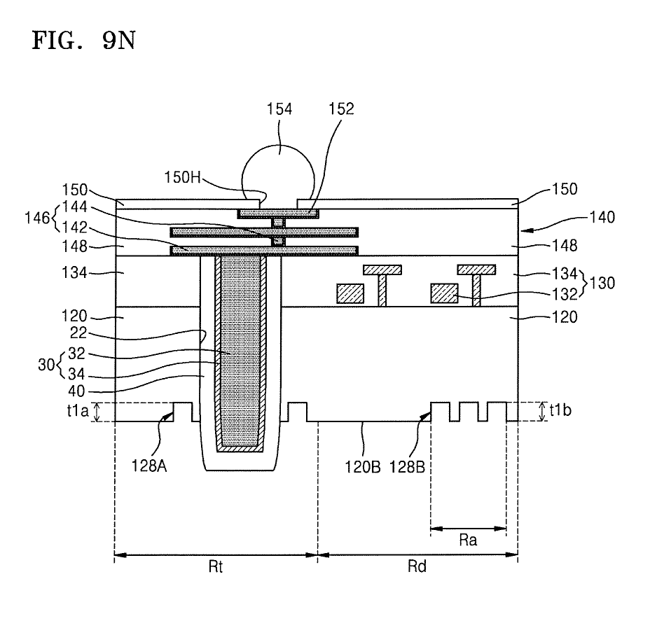

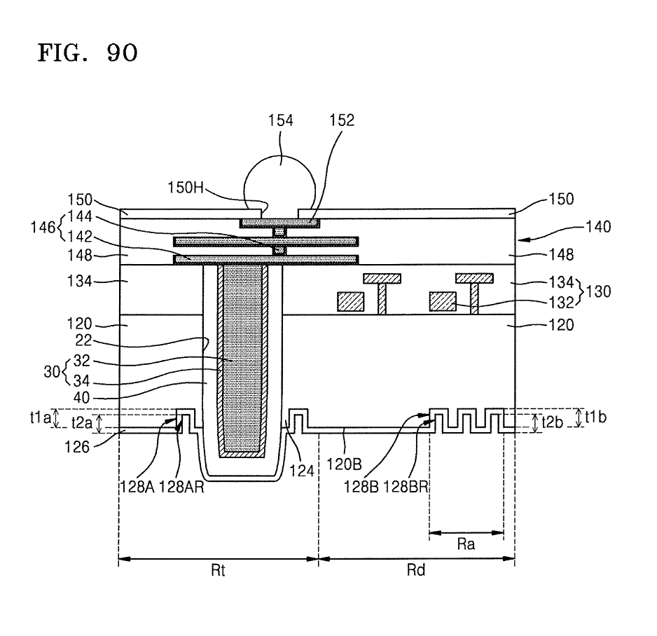

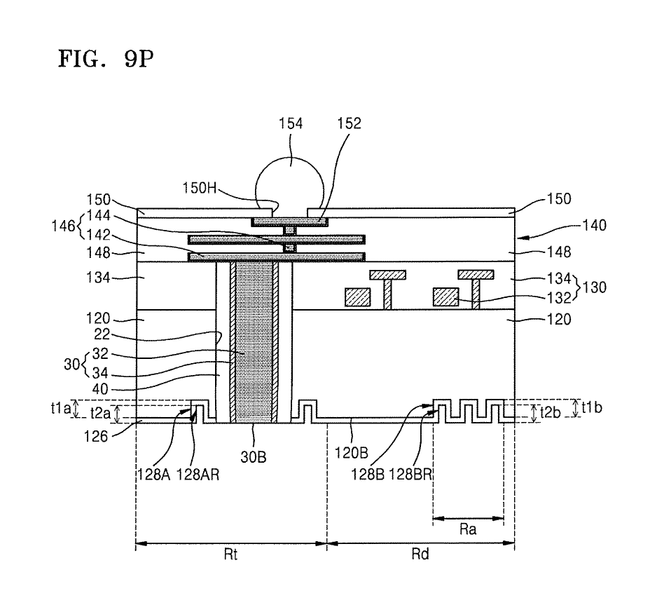

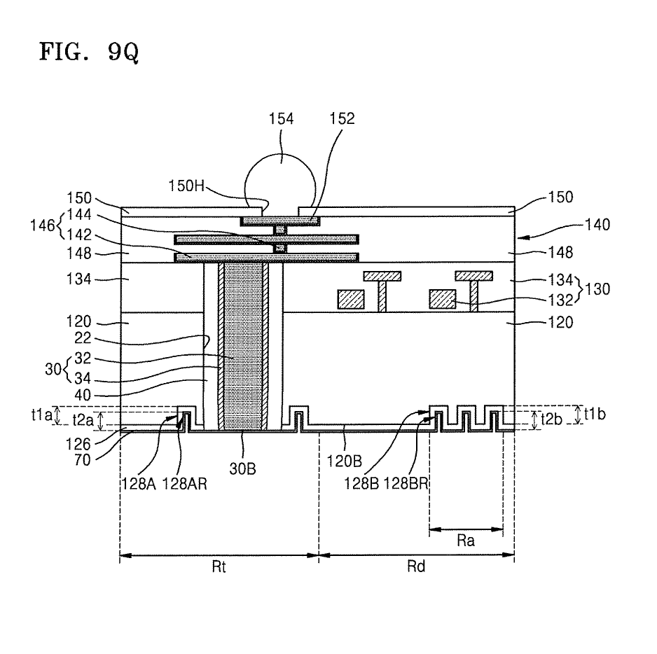

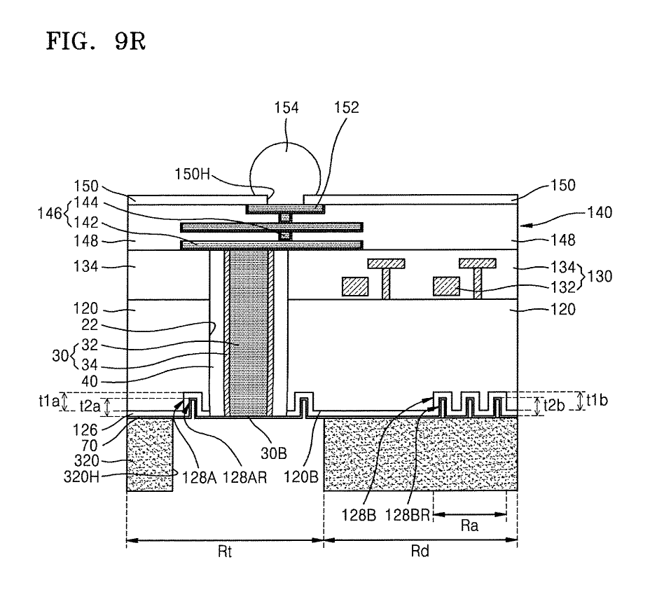

FIGS. 9A through 9R are cross-sectional views of a method of manufacturing a semiconductor chip 100A according to an exemplary embodiment of the present inventive concept. In FIGS. 9A through 9R, like reference numerals as those of FIGS. 1 to 8H may refer to the same elements, and duplicative descriptions may be omitted.

Referring to FIG. 9A, the FEOL structure 130 may be formed on the semiconductor substrate 120 and may include a plurality of individual devices 132. A first polish stop layer 135 may be formed on the FEOL structure 130, and a mask pattern 137 may be formed on the first polish stop layer 135. The plurality of individual devices 132 may be arranged in the element region Rd.

The first mask pattern 137 may includes a hole 137H partially exposing an upper surface of the first polish stop layer 135.

For example, the first polish stop layer 135 may include a silicon nitride layer or a silicon oxynitride layer. The first polish stop layer 135 may be formed to a thickness of about 200 Å to about 1000 Å. The first polish stop layer 135 may be formed by, for example, a CVD process.

The mask pattern 137 may include a photoresist layer.

Referring to FIG. 9B, the first polish stop layer 135 and the interlayer insulating layer 134 may be etched by using the mask pattern 137 as an etching mask, and the semiconductor substrate 120 may be etched to form the via hole 22. The via hole 22 may be formed in the TSV region Rt of the semiconductor substrate 120. The via hole 22 may include a first hole 22A formed in the semiconductor substrate 120 to a predetermined depth, and a second hole 22B penetrating through the interlayer insulating layer 134 and connected with the first hole 22A.

The via hole 22 may be formed by using an anisotropic etching process or a laser drilling process. For example, the via hole 22 may be formed in the semiconductor substrate 120 to have a width 22W of about 10 μm or less. The via hole 22 may have a depth 22D of from about 50 μm to about 100 μm with respect to the upper surface of the interlayer insulating layer 134. However, the width 22W and the depth 22D of the via hole 22 are not limited to the above examples, and may have various dimensions, as desired. The semiconductor substrate 120 may be exposed through the first hole 22A of the via hole 22, and the interlayer insulating layer 134 may be exposed through the second hole 22B of the via hole 22.

After forming the via hole 22, the mask pattern 137 may be removed to expose the upper surface of the first polish stop layer 135.

Referring to FIG. 9C, the via insulating layer 40 may be formed on an inner sidewall and a bottom surface of the via hole 22 and may cover the inner sidewall and the bottom surface of the via hole 22.

The via insulating layer 40 may cover the surfaces of the semiconductor substrate 120, the interlayer insulating layer 134, and the first polish stop layer 135 that are exposed in the via hole 22.

Referring to FIG. 9D, the conductive barrier layer 34 may be formed on the via insulating layer 40 in and outside the via hole 22. The conductive barrier layer 34 may be formed by a PVD process or a CVD process.

For example, the conductive barrier layer 34 may be a single layer including a single material or may have a multi-layered structure including at least two materials. The conductive barrier layer 34 may include at least one material selected from W, WN, WC, Ti, TiN, Ta, TaN, Ru, Co, Mn, WN, Ni, and NiB. For example, the conductive barrier layer 34 may have a structure in which a TaN layer having a thickness of about 50 Å to about 200 Å is disposed on a Ta layer having a thickness of about 1000 Å to about 3000 Å.

Referring to FIG. 9E, a metal layer 32P may be formed on the conductive barrier layer 34 and may fill the remaining space in the via hole 22.

The forming of the metal layer 32P may be performed while maintaining a vacuum atmosphere in which the conductive barrier layer 34 is formed, after performing the process of forming the conductive barrier layer 34 described above with reference to FIG. 9D. However, pressure when forming the conductive barrier layer 34 may be different than pressure when forming the metal layer 32P. The metal layer 32P may cover the conductive barrier layer 34 in and outside the via hole 22.

For example, the metal layer 32P may be formed by an electroplating process. A metal seed layer may be formed on the surface of the conductive barrier layer 34, and a metal layer may be grown from the metal seed layer through an electroplating process to form the metal layer 32P on the conductive barrier layer 34 and filling the via hole 22. The metal seed layer may include Cu, Cu alloy, Co, Ni, Ru, Co/Cu, or Ru/Cu. The metal seed layer may be formed by a PVD process. The metal layer 32P may include Cu or W. For example, the metal layer 32P may include Cu, CuSn, CuMg, CuNi, CuZn, CuPd, CuAu, CuRe, CuW, W, or W alloy, but exemplary embodiments of the present inventive concept are not limited thereto. The electroplating process may be performed at a temperature of from about 10° C. to about 65° C. For example, the electroplating process may be performed at room temperature. After forming the metal layer 32P the metal layer 32P may be annealed under a temperature of from about 150° C. to about 450° C.

Referring to FIG. 9F, the metal layer 32P may be polished by a chemical mechanical polishing (CMP) process by using the first polish stop layer 135 as a stopper to expose the first polish stop layer 135.

Thus, the via insulating layer 40, the conductive barrier layer 34, and the metal layer 32P that are outside the via hole 22 may be removed, and a remaining part of the metal layer 32P in the via hole 22 may become the conductive plug 32 on the conductive barrier layer 34.

Referring to FIG. 9G, the conductive plug 32 may be thermally treated. Metal particles forming the conductive plug 32 may be grown due to the thermal treatment, and thus, a surface roughness of an exposed surface of the conductive plug 32 may degrade. For example, the thermal treatment may be performed at a temperature of from about 400° C. to about 500° C.

Portions protruding to outside the via hole 22, among the metal particles grown by the thermal treatment, may be removed by the CMP process. The first polish stop layer 135 may be removed and an upper surface of the interlayer insulating layer 134 of the FEOL structure 130 may be exposed to the outside.

In the via hole 22, the TSV structure 30, including the conductive plug 32 and the conductive barrier layer 34 surrounding the conductive plug 32 may remain.

Referring to FIG. 9H, the TSV structure 30 may be cleaned, and a second polish stop layer 148A, an insulating layer 148B, and a third polish stop layer 148C may be sequentially formed on the interlayer insulating layer 134 and may be patterned to form a metal wiring hole 148H exposing the upper surface of the TSV structure 30. A peripheral portion of the TSV structure 30 may be exposed at an inlet side of the via hole 22.

The second polish stop layer 148A may be used as an etch stopper when the metal wiring hole 148H is formed.

Some parts of the TSV structure 30, the via insulating layer 40, and the interlayer insulating layer 134 may be exposed through the metal wiring hole 148A. In some exemplary embodiments of the present inventive concept, the metal wiring hole 148H may be formed so that only the upper surface of the TSV structure 30 may be exposed through the metal wiring hole 148H.

The insulating layer 148B may include tetra-ethyl-ortho-silicate (TEOS). The second and third polish stop layers 148A and 148C may include silicon nitride layers or silicon oxynitride layers. The thicknesses of the second polish stop layer 148A, the insulating layer 148B, and the third polish stop layer 148C may be determined, as desired.

Referring to FIG. 9I, the metal wiring layer 142 may be formed in the metal wiring hole 148H.

The metal wiring layer 142 may have a structure in which a wiring barrier layer 142A and a wiring metal layer 142B are sequentially stacked.

For example, to form the metal wiring layer 142, a first layer for forming the wiring barrier layer 142A and a second layer for forming the wiring metal layer 142B may be sequentially formed in the metal wiring hole 148H and on the third polish stop layer 148C and the first and second layers may be polished through a CMP process by using the third polish stop layer 148C as a stopper. While the CMP process is performed, the third polish stop layer 148C may be removed to expose an upper surface of the insulating layer 148B. Then, the metal wiring layer 142, including the wiring barrier layer 142A and the wiring metal layer 142B, may remain in the metal wiring hole 148H.

The wiring barrier layer 142A may include at least one material selected from Ti, TiN, Ta, and TaN. For example, the wiring barrier layer 142A may be formed to a thickness of from about 1000 Å to about 1500 Å by a PVD process.

The wiring metal layer 142B may include Cu. To form the wiring metal layer 142B, a Cu seed layer may be formed on a surface of the wiring barrier layer 142A, and a Cu layer may be grown from the Cu seed layer by an electroplating process. In The Cu layer may be annealed.

Referring to FIG. 9J, similar to the process of forming the metal wiring layer 142 described above with reference to FIGS. 9H and 9I, the contact plug 144 having a similar multi-layered structure as that of the metal wiring layer 142 may be formed on the metal wiring layer 142. The process of forming the metal wiring layer 142 described with reference to FIGS. 9H and 9I and the process of forming the contact plug 144 may be repeatedly performed a plurality of times, so that the multi-layered wiring structure 146, in which the plurality of metal wiring layers 142 and a plurality of contact plugs 144 are alternately connected, and a bonding pad 152 connected to the multi-layered wiring structure 146 are formed.

The multi-layered wiring structure 146 may include two metal wiring layers 142 and two contact plugs 144, but exemplary embodiments of the present inventive concept are not limited thereto. Connecting structures of the metal wiring layers 142 and the contact plugs 144 in the multi-layered wiring structure 146 illustrated in FIG. 9J are examples, and exemplary embodiments of the present inventive concept are not limited thereto.

In some exemplary embodiments of the present inventive concept, each of the plurality of metal wiring layers 142 and each of the plurality of contact plugs 144 may include at least one metal selected from W, Al, and Cu. The plurality of metal wiring layers 142 may include a same material as the plurality of contact plugs 144. In another exemplary embodiment of the present inventive concept, at least some of the plurality of metal wiring layers 142 may include different materials than the plurality of contact plugs 144.

When forming the multi-layered wiring structure 146, other multi-layered wiring structures including metal wiring layers and contact plugs that are formed simultaneously with at least some selected from the plurality of metal wiring layers 142 and the plurality of contact plugs 144 may be formed on other regions of the semiconductor substrate 120, for example, an element region Rd. Thus, the BEOL structure 140 including the inter-metal insulating layer 148 including a plurality of second polish stop layers 148A and a plurality of insulating layers 148B and the plurality of multi-layered wiring structures including the portions insulated by the inter-metal insulating layer 148 may be formed on the FEOL structure 130. The BEOL structure 140 may include a plurality of wiring structures connecting individual devices 132 included in the FEOL structure 130 to other wires formed on the semiconductor substrate 120. The BEOL structure 140 may include a seal ring protecting the wiring structures and other structures under the wiring structures against external shock or moisture.

Referring to FIG. 9K, the upper insulating layer 150, in which a hole 150H exposing the bonding pad 152 may be formed, may be formed on the BEOL structure 140, and the connection terminal 154 may be formed on the upper insulating layer 150 and may be connected to the bonding pad 152 via the hole 150H.

The upper insulating layer 150 may include a silicon oxide layer, a silicon nitride layer, a polymer, or a combination thereof.

Referring to FIG. 9L, the bottom surface of the semiconductor substrate 120 may be partially removed and the TSV structure 30 surrounded by the via insulating layer 40 may protrude from the bottom surface 120B of the semiconductor substrate 120.

Referring to FIG. 9M, a second mask pattern 310 may be formed covering the lower surface 120B of the semiconductor substrate 120. The second mask pattern 310 may simultaneously cover the via insulating layer 40. The second mask pattern 310 may include first and second holes 310H1 and 310H2 exposing parts of the lower surface 120B of the semiconductor substrate 120 corresponding to the first and second grooves 128A and 128B, respectively.

The second mask pattern 310 may include a photoresist layer.

Referring to FIG. 9N, a part of the semiconductor substrate 120 may be etched by using the second mask pattern 310 as an etching mask, and the first and second grooves 128A and 128B may be respectively formed on the TSV region Rt and the element region Rd in a lower surface of the semiconductor substrate 120. The first groove 128A may be spaced apart from the TSV structure 30. For example, the first groove 128A may be spaced apart from the via insulating layer 40 surrounding a sidewall of the TSV structure 30. A part of the semiconductor substrate 120 may be arranged between the first groove 128A and the via insulating layer 40. A portion of the element region Rd, in which the second groove 128B is formed, may be referred to as the chip alignment region Ra. The chip alignment region Ra may be in any part of the element region Rd in the lower surface 120B of the semiconductor substrate 120.

The first and second grooves 128A and 128B may have first and second depths t1a and t1b with respect to the lower surface 120B of the semiconductor substrate 120, respectively. The first and second grooves 128A and 128B may be substantially simultaneously formed by an etching process. Thus, the first depth t1a of the first groove 128A may be substantially the same depth as the second depth t1b of the second groove 128B.

The protruding portion 84 and the chip alignment marks AK may be formed by the first and second grooves 128A and 128B. Since the first groove 128A for forming the protruding portion 84 and the second groove 128B for forming the chip alignment marks AK may be substantially simultaneously formed by one etching process, additional processes might not be performed to form the protruding portion 84.

After forming the first and second grooves 128A and 128B, the lower surface 120B of the semiconductor substrate 120 may be exposed by removing the second mask pattern 310.

Referring to FIG. 9O, the lower insulating layer 126 covering the lower surface 120B of the semiconductor substrate 120 may be formed. The lower insulating layer 126 may cover a via insulating layer 40 protruding from the lower surface 120B of the semiconductor substrate 120. The lower insulating layer 126 may cover inner surfaces of the first and second grooves 128A and 128B and may respectively define the first and second recesses 128AR and 128BR in the first and second grooves 128A and 128B.

The first and second recesses 128AR and 128BR may have third and fourth depths t2a and t2b with respect to the lower surface of the lower insulating layer 126, respectively. When the first depth t1a of the first groove 128A is substantially the same depth as the second depth t1b of the second groove 128B, the third depth t2a of the first recess 128AR may also be substantially the same depth as the fourth depth t2b of the second recess 128BR, but exemplary embodiments of the present inventive concept are not limited thereto. For example, when the width of the first groove 128A is different from that of the second groove 128B, the third depth t2a may be different from the fourth depth t2b even if the value of the first depth t1a is substantially the same depth as the second depth t1b. There may be a space 24 between the via insulating layer 40 and the first recess 128AR.

The lower insulating layer 126 may be formed by a CVD process. The lower insulating layer 126 may include, for example, a silicon oxide film, a silicon nitride film, or a polymer.

Referring to FIG. 9P, a polishing process may be performed on an exposed surface of the lower insulating layer 126 and a flattened surface on the lower surface 120B of the semiconductor substrate 120 may be formed. A bottom surface 30B of the TSV structure 30 flattened on the lower surface 120B of the semiconductor substrate 120 may be exposed. The polishing process may be performed until the lower surface 120B of the semiconductor substrate 120 is not exposed anymore. Thus, the lower surface 120B of the semiconductor substrate 120, in which the TSV structure 30 and the via insulating layer 40 are not formed, may be covered by the lower insulating layer 126.

Referring to FIG. 9Q, the seed layer 70 covering the bottom surface 30B of the TSV structure 30 and the lower insulating layer 126 may be formed. The seed layer 70 may include, for example, Cu, Cu alloy, Co, Ni, Ru, Co/Cu, or Ru/Cu. The seed layer 70 may be formed by using, for example, a PVD process.

Referring to FIG. 9R, a third mask pattern 320 covering the seed layer 70 may be formed. The third mask pattern 320 may include a hole 320H exposing a part of the seed layer 70 corresponding to the connection pad 80 (see, e.g., FIG. 3). The third mask pattern 320 may expose the first recess 128AR and may cover the second recess 128BR.

The third mask pattern 320 may include a photoresist layer.

The third mask pattern 320 may be removed after forming the connection pad 80 on the seed layer 70 (see, e.g., FIG. 3), and the semiconductor chip 100A may be formed by removing a part of the seed layer 70, which may be exposed without being covered by the connection pad 80. Thus, the connection pad 80 may have a foundation base 82 and the protruding portion 84 extending to the inside of the first groove 128A. The protruding portion 84 may fill the first recess 128AR.

The connection pad 80 may include Ni, Cu, Al, Au, W, or a combination thereof, but exemplary embodiments of the present inventive concept are not limited thereto. The connection pad 80 may be formed by using, for example, an electroplating process. The electroplating process may be performed at a temperature of from about 10° C. to about 65° C. For example, the electroplating process may be performed at room temperature. After forming the connection pad 80, the connection pad 80 may be annealed at a temperature of from about 150° C. to about 450° C. The foundation base 82 and the protruding portion 84 may be integrally formed since the foundation base 82 and the protruding portion 84 may be formed together by using the electroplating process.

Although an exemplary manufacturing method of a semiconductor chip is described with reference to FIGS. 9A through 9R, those of ordinary skill in the art understand that another semiconductor chip according to exemplary embodiments of the present inventive concept may be manufactured by the manufacturing method described with reference to FIGS. 9A through 9R.

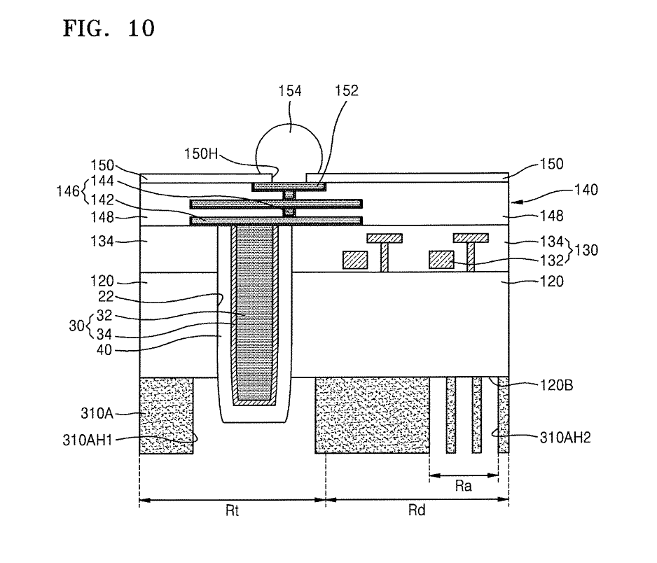

FIG. 10 is a cross-sectional view of a method of manufacturing a semiconductor chip according to an exemplary embodiment of the present inventive concept. The method of manufacturing the semiconductor chip described with reference to FIG. 10 may be substantially the same as the method described with reference to FIGS. 9A through 9L. Thus, FIG. 10 may illustrate the method of manufacturing the semiconductor chip after the steps described with reference to FIG. 9L, and descriptions of corresponding to FIGS. 9A through 9L may be omitted.

Referring to FIG. 10, a second mask pattern 310A covering a lower surface 120B of a semiconductor substrate 120 is formed. The second mask pattern 310A may expose a via insulating layer 40. The second mask pattern 310A may include a first hole 310AH1 exposing a part of the lower surface 120B of the semiconductor substrate 120 corresponding to the first groove 128A and the bottom surface 30B of the TSV structure 30, and a second hole 310AH2 exposing a part of the lower surface 120B of the semiconductor substrate 120 corresponding to the second groove 128B.

The second mask pattern 310A may include a photoresist layer.

Those of ordinary skill in the art understand that a shape of the connection pad 80 illustrated, for example, in FIG. 2 may be applied to the semiconductor chips 100A, 100B, and 100C illustrated in FIGS. 3, 4 and 5 by the manufacturing method described with reference to FIGS. 9N through 9R.

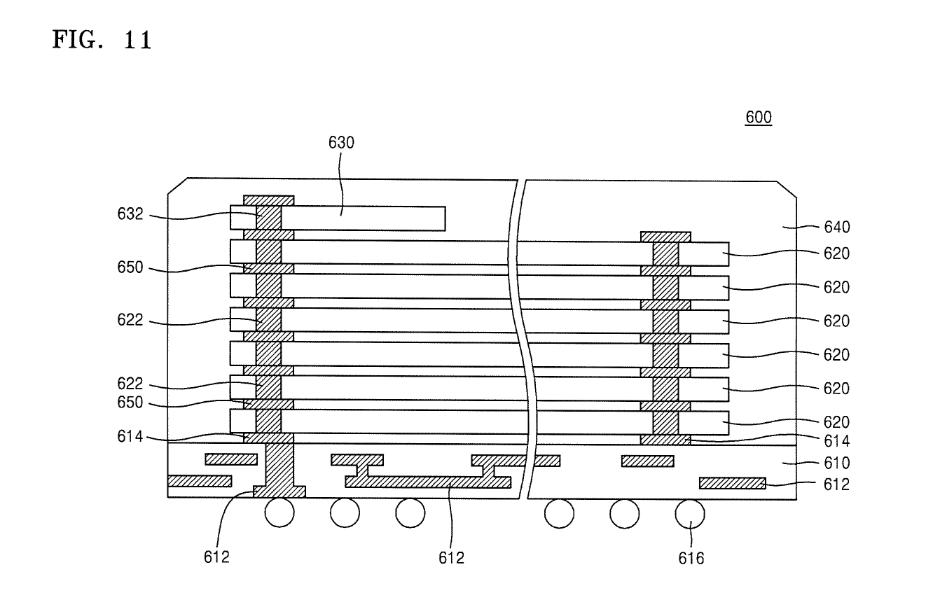

FIG. 11 is a cross-sectional view showing elements of a semiconductor package according to an exemplary embodiment of the present inventive concept.

Referring to FIG. 11, a semiconductor package 600 may include a plurality of semiconductor chips 620 that are sequentially stacked on a package substrate 610. A control chip 630 may be connected to the plurality of semiconductor chips 620. A stacked structure, including the plurality of semiconductor chips 620 and the control chip 630, may be sealed by an encapsulant 640 such as thermosetting resin on the package substrate 610. Six semiconductor chips 620 may be vertically stacked, but the number of semiconductor chips 620 and the direction in which the semiconductor chips 620 are stacked is not limited to the exemplary embodiment illustrated in FIG. 11. The number of semiconductor chips 620 may be less or larger than six. The plurality of semiconductor chips 620 may be arranged in a horizontal direction on the package substrate 610, or may be arranged in a direction combining the vertical and horizontal directions. In some exemplary embodiments of the present inventive concept, the control chip 630 may be omitted.

The package substrate 610 may be a flexible printed circuit board, a rigid printed circuit board, or a combination thereof. The package substrate 610 may include internal wires 612 and connection terminals 614. The connection terminals 614 may be disposed on a surface of the package substrate 610. A solder ball 616 may be disposed on a surface of the package substrate 610. The connection terminals 614 may be electrically connected to the solder ball 616 via the internal wires 612. In some exemplary embodiments of the present inventive concept, the solder ball 616 may be replaced with a conductive bump or a lead grid array (LGA).

Each semiconductor chip 620 may include a system LSI, flash memory, dynamic random access memory (DRAM), static random access memory (SRAM), electrically erasable programmable read-only memory (EEPROM), phase-change RAM (PRAM), magnetic random access memory (MRAM), or resistive RAM (RRAM). The control chip 630 may include logic circuits such as serializer/deserializer (SER/DES) circuits.

The plurality of semiconductor chips 620 and the control chip 630 may include TSV units 622 and 632. The TSV units 622 and 632 may be electrically connected to the connection terminals 614 of the package substrate 610 via connection members 650 such as bumps. In some exemplary embodiments of the present inventive concept, the TSV unit 632 may be omitted from the control chip 630.

At least one of the plurality of semiconductor chips 620 and the control chip 630 may include at least one selected from the semiconductor chips 10, 100A, 100B, and 100C. Each of the TSV units 622 and 632 may include the TSV structure 30. The connection members 650 may include the seed layer 70 and the connection pad 80 connected to the TSV structure 30 via the seed layer 70. The connection pad 80 may include the protruding portion 84 extending to the inside of the semiconductor structure 20 or the semiconductor substrate 120.

Thus, a connection structure between the TSV units 622 and 632 and the connection members 650 may be stabilized even when the plurality of semiconductor chips 620 and the control chip 630 are stacked, and thus, contact reliability may be increased.

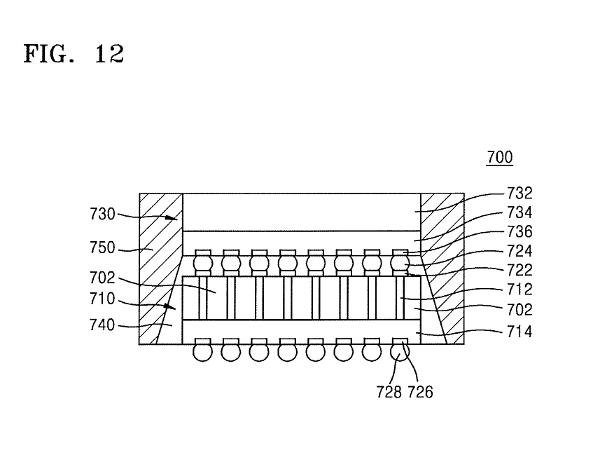

FIG. 12 is a cross-sectional view of a semiconductor package according to an exemplary embodiment of the present inventive concept.

Referring to FIG. 12, a semiconductor package 700 according to an exemplary embodiment of the present inventive concept may include a first chip 710, a second chip 730, an underfill 740, and an encapsulant 750.

The first chip 710 may have a structure of one of the semiconductor chips 10, 100A, 100B, and 100C.

The first chip 710 may include a plurality of TSV units 712 penetrating through a semiconductor structure 702. Each of the plurality of TSV units 712 may include the TSV structure 30.

The semiconductor structure 702 may include the semiconductor structure 20, or the semiconductor substrate 120.

In some exemplary embodiments of the present inventive concept, the first chip 710 may have the structure of the semiconductor chip 100A, and a device layer 714 of the first chip 710 may correspond to the BEOL structure 140. In another exemplary embodiment of the present inventive concept, the first chip 710 may have the structure of the semiconductor chip 100C, and the device layer 714 may correspond to the structure of the FEOL structure 130 and the BEOL structure 140. In another exemplary embodiment of the present inventive concept, the first chip 710 may have the structure of the semiconductor chip 100B, and the device layer 714 may be omitted.

An upper pad 722 and a connection terminal 724 that are connected to an end of each of the plurality of TSV units 712 may be disposed at a side of the first chip 710. An electrode pad 726 and a connection terminal 728 may be connected to the other side of the first chip 710. The connection terminals 724 and 728 may include solder balls or bumps.

The upper pad 722 may include the seed layer 70 and the connection pad 80 connected to the TSV structure 30 via the seed layer 70.

The second chip 730 may include a substrate 732 and a wiring structure 734 disposed on the substrate 732. An integrated circuit layer may be disposed on the substrate 732. The second chip 730 need not include a TSV structure. An electrode pad 736 may be connected to the wiring structure 734. The wiring structure 734 may be connected to the TSV units 712 via the electrode pad 736, the connection terminal 724, and the upper pad 722.

The underfill 740 may fill a connection portion between the first chip 710 and the second chip 730. The underfill 740 may fill a portion where the connection terminal 724 of the first chip 710 and the electrode pad 736 of the second chip 730 are connected to each other. The underfill 740 may include epoxy resin, and may include a silica filler or a flux. The underfill 740 may include a same material or a different material from a material included in the encapsulant 750 disposed on an outer side of the underfill 740.

The underfill 740 may surround the connection portion between the first chip 710 and the second chip 730, and side surfaces of the first chip 710. The side surfaces of the first chip 710 may be sealed by the underfill 740.

The underfill 740 may have a shape that widens in a downward direction. However, the shape of the underfill 740 is not limited thereto. For example, the underfill 740 need not surround the side surfaces of the first chip 710, and may be formed only in a space between the first chip 710 and the second chip 730.

The encapsulant 750 may seal the first chip 710 and the second chip 730. The encapsulant 750 may include a polymer, for example, an EMC. The encapsulant 750 may seal side surfaces of the second chip 730 and the underfill 740. In some exemplary embodiments of the present inventive concept, if the underfill 740 is formed only in the space between the first chip 710 and the second chip 730, the encapsulant 750 may seal the side surfaces of the first chip 710.

An upper surface of the second chip 730 need not be sealed by the encapsulant 750, and may be exposed to the outside.

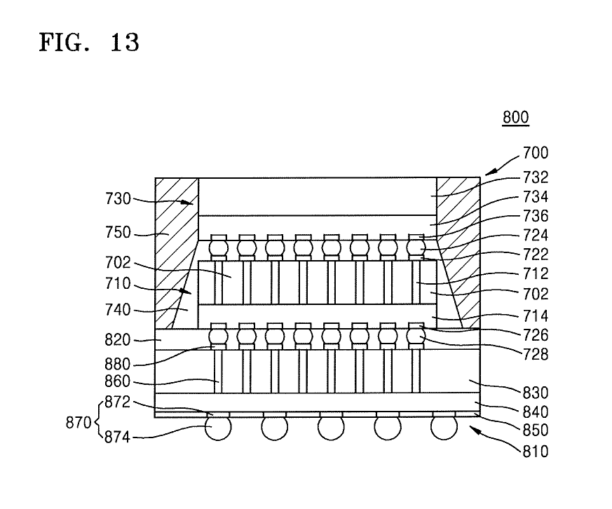

FIG. 13 is a cross-sectional view of a semiconductor package according to an exemplary embodiment of the present inventive concept. Referring to FIG. 13, like reference numerals as those of FIG. 12 may refer to same elements and duplicative descriptions may be omitted.

Referring to FIG. 13, a semiconductor package 800 according to an exemplary embodiment of the present inventive concept may include a main chip 810 and the semiconductor package 700 mounted on the main chip 810.

The semiconductor package 700 is described above with reference to FIG. 12, and thus, duplicative descriptions may be omitted.

The main chip 810 may have a horizontal cross-section which is larger than those of the first chip 710 and the second chip 730 included in the semiconductor package 700. In some exemplary embodiments of the present inventive concept, the horizontal cross-section area of the main chip 810 may be equal to a horizontal cross-section area of the semiconductor package 700 including the encapsulant 750. The semiconductor package 700 may be attached to the main chip 810 via an adhesive member 820. Bottom surfaces of the encapsulant 750 and the underfill 740 in the semiconductor package 700 may be attached to a boundary of an upper surface of the main chip 810 by the adhesive member 820.

The main chip 810 may include a body layer 830, a lower insulating layer 840, a passivation layer 850, a plurality of TSV units 860 penetrating through the body layer 830, a plurality of connection terminals 870, and an upper pad 880.

Each of the plurality of TSV units 860 may include the TSV structure 30.

An integrated circuit layer and a multi-layered wiring pattern may be included in each of the body layer 830 and the lower insulating layer 840. The integrated circuit layer and the multi-layered wiring pattern may vary depending on a kind of the main chip 810. The main chip 810 may include a logic chip, for example, a central processing unit (CPU), a controller, or an application specific integrated circuit (ASIC).

Referring to FIG. 13, the semiconductor package 700 may be disposed on the main chip 810, but the semiconductor package 700 may be directly attached to a support substrate such as a printed circuit board (PCB), or to the package substrate.

Each of the plurality of connection terminals 870 disposed on a lower portion the main chip 810 may include a pad 872 and a solder ball 874. The connection terminals 870 disposed on the main chip 810 may be larger than the connection terminals 728 formed on the semiconductor package 700.

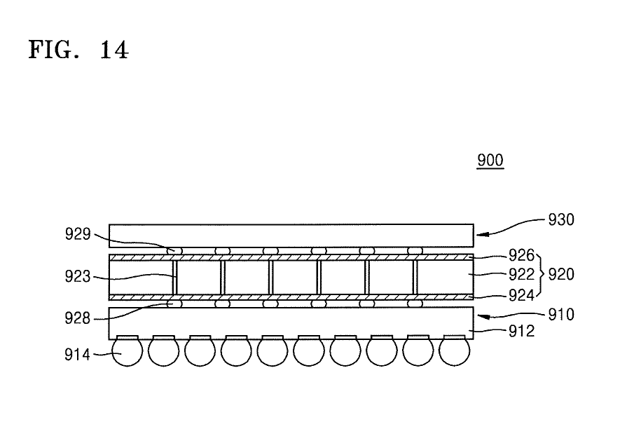

FIG. 14 is a cross-sectional view of a semiconductor package according to an exemplary embodiment of the present inventive concept.

In FIG. 14, a semiconductor package 900 may have a package on package (POP) configuration, in which a lower semiconductor package 910 and an upper semiconductor package 930 are flip-chip bonded to an interposer 920 having a TSV structure.

Referring to FIG. 14, the semiconductor package 900 may include the lower semiconductor package 910, the interposer 920 including a plurality of TSV units 923, and the upper semiconductor package 930.

Each of the plurality of TSV units 923 may include the TSV structure 30.

A plurality of first connection terminals 914 may be attached to a lower portion of a substrate 912 of the lower semiconductor package 910. The plurality of first connection terminals 914 may connect the semiconductor package 900 to a main PCB of an electronic device. In some exemplary embodiments of the present inventive concept, the plurality of first connection terminals 914 may include solder balls or solder lands.

The interposer 920 may include vertical connection terminals at fine pitches. The vertical connection terminals may connect the lower semiconductor package 910 and the upper semiconductor package 930 to each other. By using the interposer 920, a planar area of a POP integrated device may be reduced. The interposer 920 may include a silicon layer 922, through which the plurality of TSV units 923 penetrate, and redistribution layers 924 and 926 respectively formed on a bottom surface and an upper surface of the silicon layer 922, which may redistribute the plurality of TSV units 923.

In some exemplary embodiments of the present inventive concept, at least one of the redistribution layers 924 and 926 may include the seed layer 70 and the connection pad 80 connected to the TSV structure 30 via the seed layer 70.

In some exemplary embodiments of the present inventive concept, at least one of the redistribution layers 924 and 926 may be omitted.

A plurality of second connection terminals 928 connecting the plurality of TSV units 923 and the substrate 912 of the lower semiconductor package 910 to each other may be disposed on a bottom surface of the interposer 920. A plurality of third connection terminals 929 connecting the plurality of TSV units 923 and the upper semiconductor package 930 to each other may be disposed on an upper surface of the interposer 920. In some exemplary embodiments of the present inventive concept, each of the second connection terminals 928 and the third connection terminals 929 may include a solder bump or a solder land.

When the semiconductor package 900 is a semiconductor device used in a mobile phone, the lower semiconductor package 910 may be a logic device such as a processor and the upper semiconductor package 930 may be a memory device.

In some exemplary embodiments of the present inventive concept, the upper semiconductor package 930 may be a multi-chip package in which a plurality of semiconductor chips are stacked, and an upper portion of the upper semiconductor package 930 may be sealed by an encapsulant.

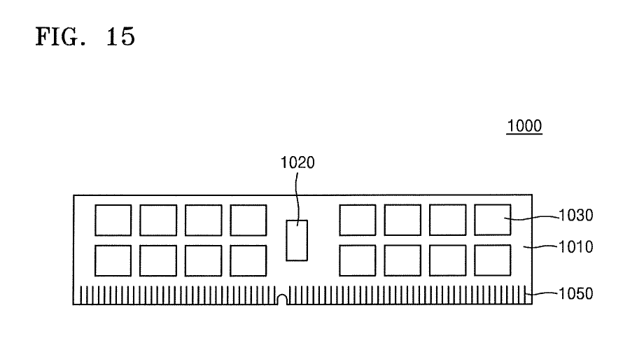

FIG. 15 is a plan view showing elements of a semiconductor module according to an exemplary embodiment of the present inventive concept.

Referring to FIG. 15, a semiconductor module 1000 may include a module substrate 1010, a control chip 1020 disposed on the module substrate 1010, and a plurality of semiconductor packages 1030. A plurality of input/output terminals 1050 may be disposed on the module substrate 1010.

The plurality of semiconductor packages 1030 may respectively include at least one selected from the semiconductor chips 10, 100A, 100B, and 100C.

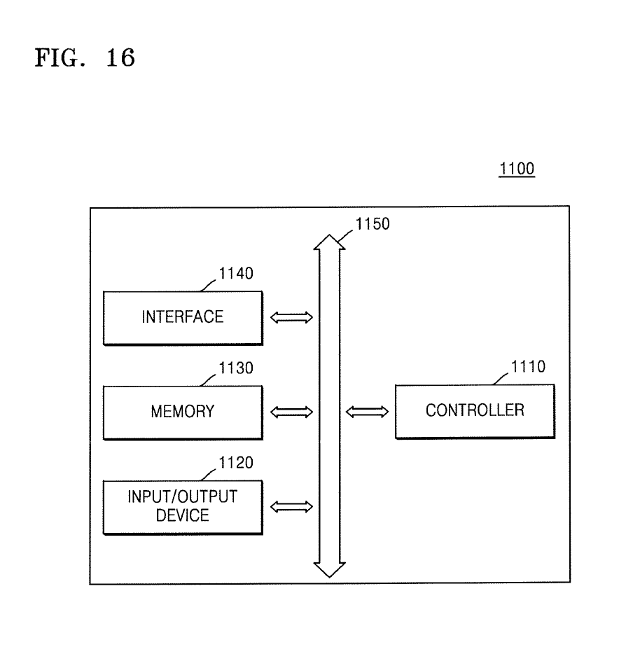

FIG. 16 is a block diagram of elements of a system according to an exemplary embodiment of the present inventive concept.

A system 1100 may include a controller 1110, an input/output device 1120, a memory 1130, and an interface 1140. The system 1100 may be a mobile system or a system transmitting or receiving information. In some exemplary embodiments of the present inventive concept, the mobile system may be at least one selected from a personal digital assistant (PDA), a portable computer, a web tablet, a wireless phone, a mobile phone, a digital music player, and a memory card.

In some exemplary embodiments of the present inventive concept, the controller 1110 may be a microprocessor, a digital signal processor, or a micro-controller.

The input/output device 1120 may input/output data to/from the system 1100. The system 1100 may be connected to an external device, for example, a personal computer or a network, by the input/output device 1120, and may exchange data with the external device. In some exemplary embodiments of the present inventive concept, the input/output device 1120 may be a keypad, a keyboard, or a display.

The memory 1130 may store code and/or data for operating the controller 1110. The memory 1130 may store data processed by the controller 1110. At least one of the controller 1110 and the memory 1130 may include at least one selected from the semiconductor chips 10, 100A, 100B, and 100C.

The interface 1140 may be a data transmission path between the system 1100 and an external device. The controller 1110, the input/output device 1120, the memory 1130, and the interface 1140 may communicate with each other via a bus 1150.

The system 1100 may be included in a mobile phone, an MP3 player, a navigation system, a portable multimedia player (PMP), a solid state disk (SSD), or a home appliance.

The semiconductor chip and the semiconductor package according to an exemplary embodiment of the present inventive concept may include a protruding portion in which a connection pad connected to a TSV structure extends to a semiconductor substrate. Thus, an adhesive strength between the semiconductor substrate and the connection pad may be increased due to increasing a contact area between the semiconductor substrate and the connection pad due to the protruding portion. It may be possible to stabilize a connection structure between the TSV structure and the connection pad as cracks, which may be generated by shear stress between the semiconductor substrate and the connection pad, may be reduced or prevented by the protruding portion, and thus contact reliability may be increased.

A manufacturing cost of the semiconductor chip and the semiconductor package according to an exemplary embodiment of the present inventive concept may be reduced since a separate process for forming the protruding portion might not be performed since etching processes for forming the protruding portion and a chip alignment mark may be performed substantially simultaneously.

While the present inventive concept has been particularly shown and described with reference to exemplary embodiments thereof, it will be understood that various changes in form and details may be made therein without departing from the spirit and scope of the present inventive concept.

What is claimed is:

1. A semiconductor chip comprising:
a semiconductor substrate;
a through-silicon-via (TSV) structure penetrating the semiconductor substrate; and
a connection pad comprising a foundation base disposed on a lower surface of the semiconductor substrate and connected to the TSV structure, and a protruding portion which protrudes from the foundation base and extends to an inside of a first groove formed in a lower surface of the semiconductor substrate.

2. The semiconductor chip of claim 1, further comprising:
a chip alignment mark including a second groove formed in the lower surface of the semiconductor substrate, wherein a depth of the first groove is substantially the same as that of the second groove.

3. The semiconductor chip of claim 2, further comprising:
a lower insulating layer covering a part of the lower surface of the semiconductor substrate and inner surfaces of the first and second grooves, and defining first and second recesses in the first and second grooves, wherein the protruding portion of the connection pad fills the first recess.

4. The semiconductor chip of claim 2, wherein the semiconductor substrate includes a TSV region in which the TSV structure is arranged and an element region in which a plurality of individual devices is arranged, and wherein the chip alignment mark is arranged in the element region.

5. The semiconductor chip of claim 1, further comprising:
a via insulating layer disposed between the TSV structure and the semiconductor substrate, wherein the via insulating layer surrounds a sidewall of the TSV structure, and wherein a part of an inner surface of the first groove is a part of the sidewall of the TSV structure.

6. The semiconductor chip of claim 1, further comprising:
a via insulating layer disposed between the TSV structure and the semiconductor substrate, wherein the via insulating layer surrounds a sidewall of the TSV structure, and wherein the first groove is spaced apart from the via insulating layer and a part of the semiconductor substrate is arranged between the protruding portion of the connection pad and the via insulating layer.

7. The semiconductor chip of claim 1, wherein the protruding portion surrounds a lower side surface of the TSV structure.

8. The semiconductor chip of claim 1, wherein a plurality of protruding portions is spaced apart from each other along a lower side surface of the TSV structure.

9. The semiconductor chip of claim 1, further comprising:
an interlayer insulating layer covering an upper surface of the semiconductor substrate, wherein the TSV structure penetrates through the semiconductor substrate and the interlayer insulating layer.

10. The semiconductor chip of claim 1, further comprising:
an interlayer insulating layer covering an upper surface of the semiconductor substrate, wherein the TSV structure does not penetrate through the interlayer insulating layer while penetrating through the semiconductor substrate.

11. The semiconductor chip of claim 1, further comprising:
an interlayer insulating layer covering an upper surface of the semiconductor substrate and an inter-metal insulating layer covering the interlayer insulating layer, wherein the TSV structure penetrates through the semiconductor substrate, the interlayer insulating layer, and the inter-metal insulating layer.

12. A semiconductor package comprising:
a plurality of semiconductor chips comprising a through-silicon-via (TSV) structure penetrating a semiconductor substrate, wherein the plurality of semiconductor chips is stacked and electrically connected to each other through the TSV structure, and wherein
each of the plurality of semiconductor chips comprises:
a connection pad comprising a foundation base disposed on a lower surface of the semiconductor substrate and connected to the TSV structure, and a protruding portion which protrudes from the foundation base and extends to an inside of a first groove formed in a lower surface of the semiconductor substrate, and
a chip alignment mark which is formed in the lower surface of the semiconductor substrate, wherein the chip alignment mark comprises a second groove having substantially a same depth as a depth of the first groove, and wherein the semiconductor chips each overlap the chip alignment mark corresponding another of the semiconductor chips.

13. The semiconductor package of claim 12, wherein
each semiconductor substrate of the plurality of semiconductor chips includes a TSV region in which the TSV structure is arranged and an element region in which a plurality of individual devices is arranged, wherein the chip alignment mark is formed in the element region.

14. The semiconductor package of claim 12, wherein each of the plurality of semiconductor chips further comprises a lower insulating layer covering a part of the lower surface of the semiconductor substrate and inner surfaces of the first and second grooves, wherein the lower insulating layer defines first and second recesses in the first and second grooves, and wherein the protruding portion of the connection pad fills the first recess.

15. The semiconductor package of claim 12, further comprising:
a package substrate, wherein each of the plurality of semiconductor chips further comprises a connection terminal which is electrically connected to the TSV structure and attached on an upper surface of the semiconductor substrate, and wherein the upper surface of the semiconductor substrate is stacked on the package substrate to face the package substrate.

16. A semiconductor chip comprising:
a semiconductor substrate;
a through-silicon-via (TSV) structure penetrating the semiconductor substrate; and
a connection pad comprising a foundation base disposed on a lower surface of the semiconductor substrate and connected to the TSV structure, and a protruding portion which protrudes from the foundation base along a lower side of the TSV structure.

17. The semiconductor chip of claim 16, further comprising:
a chip alignment mark formed in the lower surface of the semiconductor substrate, wherein the chip alignment mark has a first height, and wherein the first height is substantially the same as a second height of the protruding portion.

18. The semiconductor chip of claim 16, further comprising:
a lower insulating layer covering a part of the lower surface of the semiconductor substrate, and respectively defining a groove in the lower surface of the semiconductor substrate, wherein the protruding portion is disposed in the groove.

19. The semiconductor chip of claim 17, wherein the semiconductor substrate includes a TSV region in which the TSV structure is arranged and an element region in which a plurality of individual devices is arranged, and wherein the chip alignment mark is arranged in the element region.

20. The semiconductor chip of claim 16, further comprising:
a via insulating layer disposed between the TSV structure and the semiconductor substrate, wherein the via insulating layer surrounds a sidewall of the TSV structure.
